(19) United States
(12) Patent Application Publication
(10) Pub. No.: US 2020/0028055 A1
(43) Pub. Date: Jan. 23, 2020

(54) THERMOELECTRIC CONVERSION DEVICE

(71) Applicant: TDK CORPORATION, Tokyo (JP)

(72) Inventors: Makoto SHIBATA, Tokyo (JP); Kazuya MAEKAWA, Tokyo (JP)

(73) Assignee: TDK CORPORATION, Tokyo (JP)

(21) Appl. No.: 16/490,428

(22) PCT Filed: Jul. 31, 2017
(86) PCT No.: PCT/JP2017/027677

§ 371 Date: Aug. 30, 2019

(30) Foreign Application Priority Data
Mar. 3, 2017 (JP) 2017-040522

(51) Int. Cl. H01L 35/30; H01L 35/32

(52) U.S. Cl. CPC H01L 35/30; H01L 35/32

(57) ABSTRACT

A thermoelectric conversion device includes: thermoelectric conversion elements that are disposed on a virtual plane; a plurality of first heat transfer members that are disposed on one side with respect to the thermoelectric conversion elements in a vertical direction perpendicular to the virtual plane and that are configured to transfer heat to/from the thermoelectric conversion elements; and a plurality of heat transfer parts that are disposed on another side with respect to the thermoelectric conversion elements in the vertical direction perpendicular to the virtual plane with a space interposed therebetween in a first direction along an in-plane direction of the virtual plane, and that are configured to transfer heat to/from the thermoelectric conversion elements.

### TECHNICAL FIELD

The present disclosure relates to a thermoelectric conversion device.

Priority is claimed on Japanese Patent Application No. 2017-040522, filed Mar. 3, 2017, the content of which is incorporated herein by reference.

### BACKGROUND ART

In recent years, from the point of view of energy saving, the use of heat that dissipates without being used has attracted attention. Particularly, in the field relating to internal combustion engines and combustion apparatuses, research relating to thermoelectric conversion using exhaust heat has been actively performed.

In research on thermoelectric conversion devices, although materials of a BiTe system having high performance near room temperature has been mainstream until now, the improvement of thermoelectric efficiency as a material system has come close to its limit in addition to problems of toxicity and an increase in the material cost thereof, and thus, such materials have tended to deviate from mainstream research. Thus, in recent years, the focus of research has shifted in a direction of lowering the thermal conductivity using a quantum structure using a multiplayer film, a nano composite mixture film, or the like instead of materials of the BiTe system and improving a thermoelectric efficiency in accordance therewith.

For example, as illustrated in Patent Document 1, a thermoelectric conversion module (thermoelectric conversion device) including a substrate, a thermoelectric conversion film formed on a first surface of the substrate, a first heat transfer member disposed on the first surface side of the substrate, and a second heat transfer member disposed on a second surface side of the substrate that is positioned on a side opposite to the first surface is known.

A convex part is disposed in one surface of the first heat transfer member and the second heat transfer member. The convex part of the first heat transfer member is in contact with an electrode on a high-temperature side formed in one end portion of the thermoelectric conversion film. The convex part of the second heat transfer member is in contact with a part, which faces an electrode on a low-temperature side formed in the other end portion of the thermoelectric conversion film in the thickness direction of the substrate, of the second surface of the substrate.

### CITATION LIST

### Patent Document

[Patent Document 1]

PCT International Publication No. WO 2011/065185

### SUMMARY OF INVENTION

### Technical Problem

However, in the conventional thermoelectric conversion module described above, in a case in which the amount of heat received from the first heat transfer member is sufficiently large with respect to the amount of heat emission or the amount of cooling of the cold junction side of the thermoelectric conversion film, it becomes easy for the heat to flow into the thermoelectric conversion film. For this reason, it is easy for the temperature of the cold junction side of the thermoelectric conversion film to rise in accordance with heat transferred from the hot junction side to the cold junction side through the thermoelectric conversion film.

Accordingly, a temperature difference between the hot junction side and the cold junction side of the thermoelectric conversion film becomes small, and there is a problem in that the amount of generated power is small.

The present disclosure is realized in consideration of such situations, and an objective thereof is to provide a thermoelectric conversion device capable of acquiring a large amount of generated power.

### Solution to Problem

(1) According to the present disclosure, a thermoelectric conversion device including: thermoelectric conversion elements that are disposed on a virtual plane; a plurality of first heat transfer members that are disposed on one side with respect to t the thermoelectric conversion elements in a vertical direction perpendicular to the virtual plane and that are configured to transfer heat to/from the thermoelectric conversion elements; and a plurality of heat transfer parts that are disposed on an other side with respect to the thermoelectric conversion elements in the vertical direction perpendicular to the virtual plane with a space interposed therebetween in a first direction along an in-plane direction of the virtual plane, and that are configured to transfer heat to/from the thermoelectric conversion elements, wherein the first heat transfer members are disposed in correspondence with the heat transfer parts and are disposed to be positioned on the one side in the vertical direction opposite to the heat transfer parts, a first low heat conduction part having lower thermal conductivity than thermal conductivity of the heat transfer parts is disposed between the heat transfer parts that are adjacent to each other in the first direction, and a second low heat conduction part having lower thermal conductivity than thermal conductivity of the first heat transfer members is disposed between the first heat transfer members that are adjacent to each other in the first direction.

According to the thermoelectric conversion device relating to the present disclosure, since the first low heat conduction part having lower thermal conductivity than the thermal conductivity of the heat transfer parts is disposed between the heat transfer parts that are adjacent to each other in the first direction, transfer of heat to/from the thermoelectric conversion elements through the heat transfer parts can be performed with priority over transfer of heat through the first low heat conduction part. Accordingly, for example, in a case in which heat is transferred to the thermoelectric conversion elements through the heat transfer parts, an end portion of the thermoelectric conversion elements that is close to the heat transfer parts can be configured as an end portion of the hot junction side, and an end portion farther away from the end portion of the hot junction side when seen from the heat transfer parts in the in-plane direction of the virtual plane can be configured as an end portion of the cold junction side. Accordingly, a temperature difference can be caused to occur between the hot junction side and the cold junction side in the thermoelectric conversion elements, and an electromotive force based on a Seebeck effect is generated, whereby power generation can be achieved.

However, in the case described above, since the first heat transfer members are disposed to be positioned on the one side in the vertical direction opposite to the heat transfer parts, in accordance with a heat dissipation or cooling effect of the first heat transfer members, the heat transferred from the heat transfer parts to the thermoelectric conversion elements can be easily released to a side of the first heat transfer part rather than the heat being conducted from the hot junction side to the cold junction side inside the thermoelectric conversion elements. Accordingly, in a case in which the amount of heat received from a side of the heat transfer part is large, a part of the heat can be released through the first heat transfer members, and excessive heat can be inhibited from flowing into a side of the thermoelectric conversion elements.

Accordingly, a decrease in the temperature difference occurring between the hot junction side and the cold junction side in the thermoelectric conversion elements can be suppressed.

Particularly, since the second low heat conduction part having lower thermal conductivity than the thermal conductivity of the first heat transfer members is disposed between the first heat transfer members that are adjacent to each other in the first direction, heat transferred to the first heat transfer members can be caused not to be easily transferred in the in-plane direction of the virtual plane through the second low heat conduction part. Accordingly, as described above, a decrease in the temperature difference between the hot junction side and the cold junction side in the thermoelectric conversion elements can be inhibited, and a large amount of generated power can be achieved.

In addition, for example, also in a case in which heat is transferred from the side of the first heat transfer member to the thermoelectric conversion elements, similar to the case described above, excessive heat can be inhibited from flowing into the side of the thermoelectric conversion elements. Accordingly, a decrease in the temperature difference between the hot junction side and the cold junction side in the thermoelectric conversion elements can be inhibited, and a large amount of generated power can be achieved.

For example, since the second low heat conduction part is disposed between the first heat transfer members that are adjacent to each other in the first direction, heat transfer to/from the thermoelectric conversion elements through the first heat transfer members can be performed with priority over heat transfer through the second low heat conduction part. In this way, also in a case in which heat is transferred from the side of the first heat transfer members to the thermoelectric conversion elements, a temperature difference between the hot junction side and the cold junction side in the thermoelectric conversion elements can be caused to occur.

Contrary to the case described above, in accordance with a heat dissipation or cooling effect of the heat transfer parts, heat transferred from the first heat transfer members to the thermoelectric conversion elements can be easily released to the side of the heat transfer part than the heat being caused to conduct from the hot junction side to the cold junction side inside the thermoelectric conversion elements. In this way, in a case in which the amount of heat received from the side of the first heat transfer member is larger, a part of the heat can be released through the heat transfer parts, and excessive heat can be inhibited from flowing into the side of the thermoelectric conversion elements. Accordingly, a decrease in the temperature difference occurring between the hot junction side and the cold junction side in the thermoelectric conversion elements can be inhibited

Since the first low heat conduction part is disposed between the heat transfer parts that are adjacent to each other in the first direction, heat transferred to the heat transfer parts can be caused not to be easily transferred in the in-plane direction of the virtual plane through the first low heat conduction part. Accordingly, a decrease in the temperature difference between the hot junction side and the cold junction side in the thermoelectric conversion elements can be inhibited, and a large amount of generated power can be achieved.

(2) A second heat transfer member disposed on the other side with respect to the thermoelectric conversion elements in the vertical direction may be included, and the heat transfer parts may be disposed on the side of thermoelectric conversion elements with respect to the second heat transfer member.

In such a case, for example, the second heat transfer member can be caused to function as a heat-receiving member, and heat received from the second heat transfer member can be transferred to the thermoelectric conversion elements through the heat transfer parts with priority. Accordingly, a temperature difference between the hot junction side and the cold junction side in the thermoelectric conversion elements can be effectively increased.

In addition, for example, in a case in which heat is transferred from the side of the first heat transfer member to the thermoelectric conversion elements, the heat dissipation or cooling effect using the second heat transfer member can be used, and accordingly, heat transferred to the first heat transfer members to the thermoelectric conversion elements can be easily released to a side of the second heat transfer member through the heat transfer parts rather than the heat being caused to conduct from the hot junction side to the cold junction side inside the thermoelectric conversion elements. In this way, in a case in which the amount of heat received from the side of the first heat transfer member is large, a part of the heat can be effectively released through the heat transfer parts and the second heat transfer member. Accordingly, a decrease in the temperature difference occurring between the hot junction side and the cold junction side in the thermoelectric conversion elements can be inhibited.

(3) The first low heat conduction part and the second low heat conduction part may be air gap portions.

In such a case, since the first low heat conduction part and the second low heat conduction part are air gap portions, a so-called gap filled with air, the first low heat conduction part and the second low heat conduction part can be conveniently configured. In addition, since the thermal conductivity of the first low heat conduction part and the second low heat conduction part can be configured to be markedly lower than that of the heat transfer parts and the first heat transfer members, heat can be transferred to/from the thermoelectric conversion elements through the heat transfer parts and the first heat transfer members more selectively. Furthermore, since it becomes difficult for heat transferred to the heat transfer parts or the first heat transfer members to be further transferred in the in-plane direction of the virtual plane through the heat transfer parts or the first heat transfer members, it is easy to acquire a large amount of generated power.

(4) A substrate that includes a first surface and a second surface facing each other in the vertical direction and is disposed along the virtual plane may be included, and the substrate may be disposed between the thermoelectric conversion elements and the first heat transfer members in a state in which the first surface is directed toward the side of the thermoelectric conversion elements, and the second surface is directed toward the side of the first heat transfer members.

In such a case, since the substrate is disposed between the thermoelectric conversion elements and the first heat transfer members, this substrate can be used as a support substrate, and the thermoelectric conversion elements and the first heat transfer members can be disposed in a more stable state. Accordingly, the operations and the effects described above can be successfully achieved more stably. In addition, a higher-quality thermoelectric conversion device, in which the rigidity of the entire thermoelectric conversion device can be easily increased, and it is difficult for deformations, for example, bending, distortion, and the like to occur, can be configured, and the practicability as a product can be improved.

In addition, also in such a case, for example, by decreasing the thickness of the substrate, conduction of heat inside the substrate can be inhibited, and accordingly, operations and effects similar to the operations and the effects described above can be successfully achieved.

(5) The second low heat conduction part may be disposed at a middle position of the first heat transfer members that are adjacent to each other in the first direction.

In such a case, since it becomes more difficult to transfer heat to the cold junction side of the thermoelectric conversion elements, a temperature difference between the hot junction side and the cold junction side in the thermoelectric conversion elements can be further increased, and a larger amount of generated power can be achieved.

(6) Third heat transfer members that are disposed on the one side with respect to the thermoelectric conversion elements in the vertical direction and that are configured to transfer heat to/from the thermoelectric conversion elements may be further included, and each of the third heat transfer members may be disposed at a middle position of the first heat transfer members that are adjacent to each other in the first direction and each of the third heat transfer members has higher thermal conductivity than the second low heat conduction part.

In such a case, for example, in a case in which heat is transferred to the thermoelectric conversion elements through the heat transfer parts, in accordance with a heat dissipation or cooling effect of the third heat transfer members, an end portion of the thermoelectric conversion elements on the cold junction side can be cooled through the third heat transfer members. Accordingly, both a heat dissipation or cooling effect of the first heat transfer members and a heat dissipation or cooling effect of the third heat transfer members can be used, and accordingly, it is difficult to be influenced by the amount of heat received from the side of the heat transfer member, and a temperature difference between the hot junction side and the cold junction side in the thermoelectric conversion elements can be stably increased. Accordingly, a large amount of generated power can be achieved more stably. Therefore, this is particularly effective in a case in which heat is transferred to the thermoelectric conversion elements through the heat transfer part.

(7) A width of the first heat transfer member in the first direction may be larger than a width of the third heat transfer member in the first direction.

In such a case, since a heat dissipation or cooling effect of the first heat transfer members can be configured to be successfully achieved more effectively than a heat dissipation or cooling effect of the third heat transfer members, and accordingly, particularly in a case in which the amount of heat received from the side of the heat transfer part is large, a part of the heat can be easily released to the outside through the first heat transfer member. For this reason, flow of a large amount of heat into the side of the thermoelectric conversion elements can be effectively inhibited. Accordingly, a temperature difference between the hot junction side and the cold junction side in the thermoelectric conversion elements can be increased, and a large amount of generated power can be achieved.

(8) A width of the third heat transfer member in the first direction may be larger than a width of the first heat transfer member in the first direction.

In such a case, since the heat dissipation or cooling effect of the third heat transfer members can be successfully achieved more effectively than the heat dissipation or cooling effect of the first heat transfer member, the cold junction side of the thermoelectric conversion elements can be effectively cooled using the heat dissipation or cooling effect of the third heat transfer members. Accordingly, a temperature difference between the hot junction side and the cold junction side in the thermoelectric conversion elements can be increased, and a large amount of generated power can be achieved.

(9) A fourth heat transfer member disposed on the one side with respect to the first heat transfer members and the third heat transfer members in the vertical direction may be further included, and the fourth heat transfer member may be thermally bonded to the third heat transfer members and are configured to transfer heat to/from the thermoelectric conversion elements through the third heat transfer members rather than through the first heat transfer members.

In such a case, for example, in a case in which heat is transferred to the thermoelectric conversion elements through the heat transfer parts, in accordance with the heat dissipation or cooling effect of the fourth heat transfer member, the end portion of the thermoelectric conversion elements on the cold junction side can be further cooled through the third heat transfer members and the fourth heat transfer member. Accordingly, by further increasing a temperature difference between the hot junction side and the cold junction side in the thermoelectric conversion elements, a larger amount of generated power can be achieved. Accordingly, this is particularly effective in a case in which heat is transferred to the thermoelectric conversion elements through the heat transfer parts.

(10) In the thermoelectric conversion device described in any one of (1) to (5), a thermoelectric conversion module in which the thermoelectric conversion elements and the first heat transfer members are piled up in the vertical direction in multiple layers may be further included, and, when a direction toward the other side in the vertical direction is set as an upward direction, the heat transfer parts may be disposed on the other side in the vertical direction with respect to the thermoelectric conversion elements positioned in an uppermost layer in the vertical direction among the thermoelectric conversion elements piled up in multiple layers, and the thermoelectric conversion elements positioned in a layer other than the uppermost layer in the vertical direction among the thermoelectric conversion elements piled up in multiple layers may be thermally bonded to the first heat transfer members positioned in a layer above thereof and may be configured to transfer heat to/from the thermoelectric conversion elements positioned in the layer above through the first heat transfer members positioned in the layer above rather than through the second low heat conduction part positioned in the layer above.

In such a case, since the thermoelectric conversion module is included, for example, in a case in which heat is transferred to the thermoelectric conversion elements positioned in the uppermost layer through heat transfer parts, heat dissipated through the first heat transfer members positioned in the uppermost layer can be transferred to an end portion of the thermoelectric conversion elements positioned on the layer below thereof on the hot junction side, and a larger amount of generated power can be achieved using this thermoelectric conversion elements. Accordingly, the dissipated heat can be effectively used, and power generation in the thermoelectric conversion elements of each layer can be achieved. Therefore, a large amount of generated power can be achieved with a high efficiency.

(11) The thermoelectric conversion device described in any one of (6) to (8), a thermoelectric conversion module in which the thermoelectric conversion elements, the first heat transfer members, and the third heat transfer members are piled up in the vertical direction in multiple layers may be further included, and, when a direction toward the other side in the vertical direction is set as an upward direction, the heat transfer parts may be disposed on the other side in the vertical direction with respect to the thermoelectric conversion elements positioned in an uppermost layer in the vertical direction among the thermoelectric conversion elements piled up in multiple layers, and the thermoelectric conversion elements positioned in a layer other than the uppermost layer in the vertical direction among the thermoelectric conversion elements piled up in multiple layers may be thermally bonded to the first heat transfer members and the third heat transfer members positioned in a layer above thereof and may be configured to transfer heat to/from the thermoelectric conversion elements positioned in the layer above through the first heat transfer members and the third heat transfer members positioned in the layer above rather than through the second low heat conduction part positioned in the layer above.

In such a case, since the thermoelectric conversion module is included, for example, in a case in which heat is transferred to the thermoelectric conversion elements positioned in the uppermost layer through the heat transfer parts, heat dissipated through the first heat transfer member positioned in the uppermost layer can be transferred to an end portion of the thermoelectric conversion elements positioned on the layer below thereof on the hot junction side, and a larger amount of generated power can be achieved using this thermoelectric conversion elements. In this way, the dissipated heat can be effectively used, and power generation in the thermoelectric conversion elements of each layer can be achieved. Accordingly, a large amount of generated power can be achieved with a high efficiency.

In addition, by using the heat dissipation or cooling effect using the third heat transfer members, an end portion of the thermoelectric conversion elements on the cold junction side can be effectively cooled through the third heat transfer member positioned in the lowermost layer. For this reason, as a result, the end portion of the thermoelectric conversion elements of each layer on the cold junction side can be effectively cooled through the third heat transfer member of each layer, and a temperature difference between the hot junction side and the cold junction side in the thermoelectric conversion elements of each layer can be increased.

(12) In the thermoelectric conversion device described in (11), a fourth heat transfer member disposed on the one side in the vertical direction with respect to the first heat transfer member and the third heat transfer member positioned in a lowermost layer in the vertical direction among the first heat transfer members and the third heat transfer members piled up in multiple layers may be further included, and the fourth heat transfer member may be thermally bonded to the third heat transfer members positioned in the lowermost layer and may be configured to transfer heat to/from the thermoelectric conversion elements positioned in the lowermost layer through the third heat transfer members positioned in the lowermost layer rather than through the first heat transfer members positioned in the lowermost layer.

In such a case, for example, in a case in which heat is transferred to the thermoelectric conversion elements positioned in the uppermost layer through the heat transfer parts, the heat dissipation or cooling effect of the fourth heat transfer member can be used, and accordingly, the end portion of the thermoelectric conversion elements of each layer on the cold junction side can be cooled more effectively through the third heat transfer member of each layer. Accordingly, a temperature difference between the hot junction side and the cold junction side in the thermoelectric conversion elements of each layer can be increased more effectively.

(13) In the thermoelectric conversion device described in (10), fifth heat transfer member disposed on the one side in the vertical direction with respect to the first heat transfer members positioned in a lowermost layer in the vertical direction among the first heat transfer members piled up in multiple layers may be further included, and the fifth heat transfer member may be thermally bonded to the first heat transfer members positioned in the lowermost layer and may be configured to transfer heat to/from the thermoelectric conversion elements positioned in the lowermost layer through the first heat transfer members positioned in the lowermost layer than through the second low heat conduction part positioned in the lowermost layer.

In such a case, the fifth heat transfer member can be used as a power receiving member, and a case in which heat is transferred from the fifth heat transfer member side can be also handled. In other words, heat received from the fifth heat transfer member can be transferred to the end portion of the thermoelectric conversion elements positioned in the lowermost layer on the hot junction side through the first heat transfer members positioned in the lowermost layer, and heat dissipated from the thermoelectric conversion elements positioned in the lowermost layer can be transferred to the end portion of the thermoelectric conversion elements positioned in the second layer on the hot junction side through the first heat transfer members positioned in the second layer.

In this way, also in a case in which heat is transferred from a side of the fifth heat transfer member, the dissipated heat can be effectively used, and power generation in the thermoelectric conversion elements of each layer can be achieved. Accordingly, a large amount of generated power can be achieved with a high efficiency.

In addition, also a case in which heat is transferred to the thermoelectric conversion elements positioned in the uppermost layer through the heat transfer parts, and heat is transferred to the thermoelectric conversion elements positioned in the lowermost layer through the fifth heat transfer member, in other words, a case in which heat is transferred from both parties in the vertical direction can be appropriately handled.

### Advantageous Effects of Invention

According to the present disclosure, excessive heat can be inhibited from flowing into the side of the thermoelectric conversion elements and a large amount of generated power can be achieved by securing a temperature difference occurring between a hot junction side and a cold junction side in the thermoelectric conversion elements. Therefore, a high-quality and high-performance thermoelectric conversion device having a superior thermoelectric conversion efficiency can be configured.

### BRIEF DESCRIPTION OF DRAWINGS

FIG. 1 is an exploded perspective view illustrating a thermoelectric conversion device according to a first embodiment of the present disclosure.

FIG. 2 is a plan view of a thermoelectric conversion circuit module illustrated in FIG. 1.

FIG. 3 is a longitudinal sectional view of a thermoelectric conversion device taken along line A-A illustrated in FIG. 1.

FIG. 4 is a longitudinal sectional view (a longitudinal sectional view corresponding to a viewpoint of FIG. 3) illustrating a thermoelectric conversion device according to a second embodiment of the present disclosure.

FIG. 5 is a diagram illustrating a modified example of the second embodiment and is a longitudinal sectional view (a longitudinal sectional view corresponding to the viewpoint of FIG. 3) of a thermoelectric conversion device.

FIG. 6 is a diagram illustrating another modified example of the second embodiment and is a longitudinal sectional view (a longitudinal sectional view corresponding to the viewpoint of FIG. 3) of a thermoelectric conversion device.

FIG. 7 is a longitudinal sectional view (a longitudinal sectional view corresponding to a viewpoint of FIG. 3) of a thermoelectric conversion device according to a third embodiment of the present disclosure.

FIG. 8 is a diagram illustrating a modified example of the third embodiment and is a longitudinal sectional view (a longitudinal sectional view corresponding to the viewpoint of FIG. 3) of a thermoelectric conversion device.

FIG. 9 is a longitudinal sectional view (a longitudinal sectional view corresponding to a viewpoint illustrated in FIG. 3) of a thermoelectric conversion device according to a fourth embodiment of the present disclosure.

FIG. 10 is a longitudinal sectional view (a longitudinal sectional view corresponding to a viewpoint illustrated in FIG. 3) of a thermoelectric conversion device according to a fifth embodiment of the present disclosure.

FIG. 11 is a longitudinal sectional view (a longitudinal sectional view corresponding to a viewpoint illustrated in FIG. 3) of a thermoelectric conversion device according to a sixth embodiment of the present disclosure.

FIG. 12 is a diagram illustrating a modified example of the sixth embodiment and is a longitudinal sectional view (a longitudinal sectional view corresponding to a viewpoint illustrated in FIG. 3) of a thermoelectric conversion device.

FIG. 13 is a diagram illustrating another modified example of the first embodiment and is a longitudinal sectional view (a longitudinal sectional view corresponding to a viewpoint illustrated in FIG. 3) of a thermoelectric conversion device.

FIG. 14 is a diagram illustrating yet another modified example of the first embodiment and is a longitudinal sectional view (a longitudinal sectional view corresponding to a viewpoint illustrated in FIG. 3) of a thermoelectric conversion device.

FIG. 15 is a diagram illustrating yet another modified example of the first embodiment and is a longitudinal sectional view (a longitudinal sectional view corresponding to a viewpoint illustrated in FIG. 3) of a thermoelectric conversion device.

FIG. 16 is a plan view of a thermoelectric conversion film illustrated in FIG. 15 that is seen from a side above.

FIG. 17 is a diagram illustrating yet another modified example of the first embodiment and is a longitudinal sectional view (a longitudinal sectional view corresponding to a viewpoint illustrated in FIG. 3) of a thermoelectric conversion device.

FIG. 18 is a diagram illustrating another modified example of the fifth embodiment and is a longitudinal sectional view (a longitudinal sectional view corresponding to a viewpoint of FIG. 3) of a thermoelectric conversion device.

### DESCRIPTION OF EMBODIMENTS

### First Embodiment

Hereinafter, a thermoelectric conversion device according to a first embodiment of the present disclosure will be described with reference to the drawings.

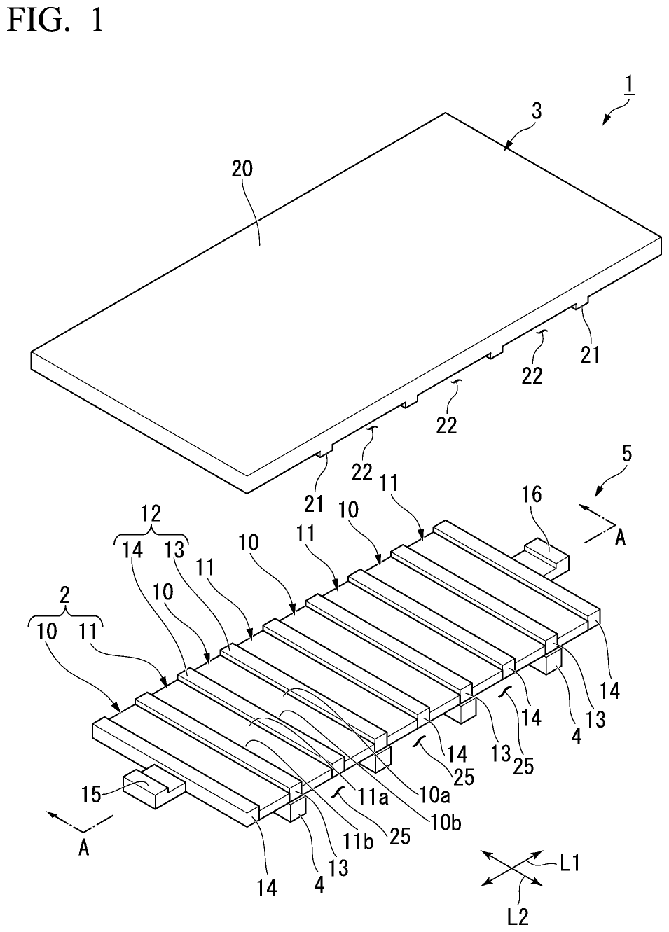

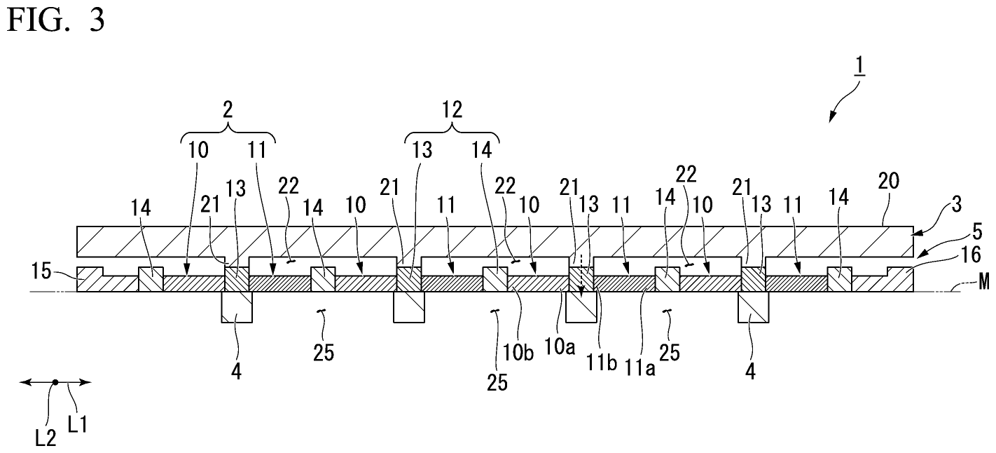

As illustrated in FIGS. 1 to 3, the thermoelectric conversion device 1 according to this embodiment includes: a thermoelectric conversion film (the thermoelectric conversion elements according to the present disclosure) 2 disposed on a virtual plane M (see FIG. 3); a first heat transfer member (a first heat transfer member according to the present disclosure) 4 that is disposed on a one side with respect to the thermoelectric conversion film 2 in the thickness direction of the thermoelectric conversion film 2 (in other words, one side in a vertical direction perpendicular to the virtual plane M) and transfers heat from/to the thermoelectric conversion film 2; and a second heat transfer member (a second heat transfer member according to the present disclosure) 3 that is disposed on an other side with respect to the thermoelectric conversion film 2 in the thickness direction of the thermoelectric conversion film 2 (in other words, the other side in the vertical direction perpendicular to the virtual plane M).

In this embodiment, a side of a second heat transfer member 3 in the thickness direction of the thermoelectric conversion film 2 (the other side in the thickness direction) will be referred to as a side above, and a direction opposite thereto (one side in the thickness direction) will be referred to as a side below. In other words, a direction from the thermoelectric conversion film 2 to the second heat transfer member 3 will be referred to as an upward direction, and a direction opposite thereto will be referred to as a downward direction. In addition, one direction out of directions along the in-plane of the virtual plane M will be referred to as a first direction L1, and a direction orthogonal to the first direction L1 will be referred to as a second direction L2.

In this embodiment, a case in which heat is transferred from the side of the second heat transfer member 3 to a side of the thermoelectric conversion film 2 will be described as an example. However, the embodiment is not limited to such a case, and heat may be transferred from the side of the first heat transfer member 4 to the side of the thermoelectric conversion film 2.

### (Thermoelectric Conversion Film)

The thermoelectric conversion film 2 includes a plurality of first thermoelectric conversion films 10 and a plurality of second thermoelectric conversion films 11.

The first thermoelectric conversion films 10 and the second thermoelectric conversion films 11 are arranged to be alternately aligned with a constant gap interposed therebetween along a first direction L1. In this embodiment, the number of first thermoelectric conversion films 10 and the number of second thermoelectric conversion films 11 are the same, and, more specifically, both the numbers are four.

However, the number of the first thermoelectric conversion films 10 and the number of second thermoelectric conversion films 11 are not limited to four and, for example, may be appropriately changed in accordance with the whole size, a use, a use environment, and the like of the thermoelectric conversion device 1.

As described above, since the first thermoelectric conversion films 10 and the second thermoelectric conversion films 11 are alternately arranged along the first direction L1, one of the first thermoelectric conversion films 10 is positioned on the outermost side of a one-direction side along the first direction L1, and one of the second thermoelectric conversion films 11 is positioned on the outermost side of the other-direction side along the first direction L1.

In this embodiment, the one-direction side on which one of the first thermoelectric conversion films 10 is positioned on the outermost side will be referred to as a front side, and the other-direction side on which one of the second thermoelectric conversion films 11 is positioned on the outermost side will be referred to as a rear side.

Each of the first thermoelectric conversion film 10 and each of the second thermoelectric conversion film 11 are formed in a rectangular shape that is longer in the second direction L2 than in the first direction L1 and are formed to have the same shape and the same size. These first thermoelectric conversion films 10 and second thermoelectric conversion films 11, for example, are formed as semiconductor multi-layer films that have a constant thickness and secure predetermined rigidity.

More specifically, each first thermoelectric conversion film 10 is formed as a multilayer film of n-type silicon (Si) and an n-type silicon•germanium alloy (SiGe) in which antimony (Sb) of a high density (for example, 10¹⁸ to 10¹⁹ cm⁻³) is doped and functions as an n-type semiconductor. Each second thermoelectric conversion film 11 is formed as a multilayer film of p-type silicon (Si) and a p-type silicon•germanium alloy (SiGe) in which boron (B) of a high density (for example, 10¹⁸ to 10¹⁹cm⁻³) is doped and functions as a p-type semiconductor.

Accordingly, a current flows from a cold junction side to a hot junction side (in other words, from a side of a second electrode 14 to a side of a first electrode 13 to be described later) in the first thermoelectric conversion film 10 that is the n-type semiconductor, and a current flows from the cold junction side to the hot junction side (in other words, from the side of the first electrode 13 to the second electrode 14 to be described later) in the second thermoelectric conversion film 11 that is the p-type semiconductor.

In addition, a plurality of first thermoelectric conversion films 10 may be either n-type semiconductor multilayer films having the same configuration or n-type semiconductor multilayer films having mutually different configurations. Similarly, a plurality of second thermoelectric conversion films 11 may be either p-type semiconductor multilayer films having the same configuration or p-type semiconductor multilayer films having mutually different configurations.

Furthermore, the first thermoelectric conversion films 10 and the second thermoelectric conversion films 11 are not limited to semiconductor multilayer films and may be single-layer films of p-type or n-type semiconductor. In addition, semiconductor of an oxide may be used as semiconductor. Furthermore, the first thermoelectric conversion films 10 and the second thermoelectric conversion films 11, for example, may be formed using other thermoelectric conversion films such as organic polymer films, metal films, or the like.

### (Electrode)

An electrode 12 is disposed between the first thermoelectric conversion film 10 and the second thermoelectric conversion film 11. The electrode 12 is bonded to the first thermoelectric conversion film 10 and the second thermoelectric conversion film 11 and electrically connects the first thermoelectric conversion film 10 and the second thermoelectric conversion film 11 that are adjacent to each other in the first direction L1.

Each electrode 12, as described above, is not only disposed between the first thermoelectric conversion film 10 and the second thermoelectric conversion film 11 but also disposed such that it is positioned on a further front side of a first thermoelectric conversion film 10 positioned on the front-most side and is bonded to this first thermoelectric conversion film 10. Furthermore, the electrode 12 is disposed such that it is positioned on a further rear side of a second thermoelectric conversion film 11 positioned in the rearmost side and is bonded to this second thermoelectric conversion film 11.

The electrode 12 is formed in an oblong shape that is long in the second direction L2 in plan view and is formed such that a length in the second direction L2 is a length equal to those of the first thermoelectric conversion film 10 and the second thermoelectric conversion film 11.

However, the length of the electrode 12 in the second direction L2 may be longer than or shorter than those of the first thermoelectric conversion film 10 and the second thermoelectric conversion film 11.

The electrode 12 is formed to have a thickness larger than the thicknesses of the first thermoelectric conversion film 10 and the second thermoelectric conversion film 11 and protrudes to the side above the first thermoelectric conversion film 10 and the second thermoelectric conversion film 11.

However, the thickness is not limited to that of such a case, and, for example, the thickness of the electrode 12 may be equal to the thicknesses of the first thermoelectric conversion film 10 and the second thermoelectric conversion film 11 or may be smaller than the thicknesses of the first thermoelectric conversion film 10 and the second thermoelectric conversion film 11.

Among the plurality of electrodes 12, each electrode 12 that is adjacent to the first thermoelectric conversion film 10 and is positioned on the rear side of the first thermoelectric conversion film 10 functions as a first electrode 13. Among the plurality of electrodes 12, the remaining electrodes 12, in other words, each electrode 12 that is adjacent to the first thermoelectric conversion film 10 and is positioned on the front side of the first thermoelectric conversion film 10 functions as a second electrode 14. In addition, the electrode 12 positioned on the rearmost side also functions as the second electrode 14.

Accordingly, a rear end portion 10a of each first thermoelectric conversion film 10 is brought into contact with the first electrode 13 over the entire length in the second direction L2. In addition, a front end portion 10b of each first thermoelectric conversion film 10 is brought into contact with the second electrode 14 over the entire length in the second direction L2.

Accordingly, a front end portion 11b of each second thermoelectric conversion film 11 is brought into contact with the first electrode 13 over the entire length in the second direction L2. In addition, a rear end portion 11a of each second thermoelectric conversion film 11 is brought into contact with the second electrode 14 over the entire length in the second direction L2.

Accordingly, the first thermoelectric conversion films 10 and the second thermoelectric conversion films 11 are electrically connected in series through the first electrodes 13 and the second electrodes 14.

In the example illustrated in FIGS. 1 to 3, each first electrode 13 is thermally connected to the second heat transfer member 3 through a convex part 21 to be described later and has a function of transferring heat from the second heat transfer member 3 to the rear end portion 10a of the first thermoelectric conversion film 10 and the front end portion 11b of the second thermoelectric conversion film 11. Accordingly, the first electrode 13 functions as a hot junction. On the other hand, the second electrode 14 is positioned in the middle of the first electrodes 13 adjacent to each other in the first direction L1 and functions as a cold junction.

In addition, the rear end portion 10a of the first thermoelectric conversion film 10 and the front end portion 11b of the second thermoelectric conversion film 11 function as an end portion of the hot junction side disposed at positions close to the convex part 21. On the other hand, the front end portion 10b of the first thermoelectric conversion film 10 and the rear end portion 11a of the second thermoelectric conversion film 11 are disposed at positions farther away from the end portion (the rear end portion 10a and the front end portion 11b) of the above-described hot junction side in the in-plane direction of the virtual plane M when seen from the convex part 21 and function as an end portion of the cold junction side.

In addition, as a material of the electrode 12, for example, a material which has high conductivity and high thermal conductivity is preferable, and a metal material such as copper (Cu), gold (Au), or the like is particularly preferable.

However, the material of the electrode 12 is not particularly limited to a metal material, and the electrode may be formed using a material having thermal conductivity higher than the terminal conductivity of the air.

### (Terminal)

A first terminal 15 and a second terminal 16 are further bonded to the second electrode 14.

The first terminal 15 is disposed to be positioned on a further front side of the second electrode 14 that is positioned on the front-most side and is bonded and electrically connected to the second electrode 14. The second terminal 16 is disposed to be positioned on a further rear side of the second electrode 14 that is positioned on the rearmost side and is bonded and electrically connected to this second electrode 14.

The first thermoelectric conversion film 10, the second thermoelectric conversion film 11, the first electrode 13, the second electrode 14, the first terminal 15, and the second terminal 16 described above configure a thermoelectric conversion circuit module 5 achieved by combining these members.

The thermoelectric conversion circuit module 5 is a module having predetermined rigidity and, for example, has a configuration in which it is difficult for unintended deformation such as bending or distortion to occur.

In addition, the thermoelectric conversion circuit module 5, for example, can be manufactured using the following method using a dummy substrate having predetermined rigidity.

First, films to become a first thermoelectric conversion film 10 and a second thermoelectric conversion film 11 are formed on an upper face of a dummy substrate, for example, by using a sputtering device, and thereafter, the films are selectively patterned through an etching process, whereby the first thermoelectric conversion film 10 and the second thermoelectric conversion film 11 are formed.

Thereafter, electrodes and terminals including a first electrode 13, a second electrode 14, a first terminal 15, and a second terminal 16 are formed on the upper face of the dummy substrate in which the first thermoelectric conversion film 10 and the second thermoelectric conversion film 11 are formed. At this time, for example, by forming a metal film and thereafter selectively patterning the metal layer through an etching process, each electrode and each terminal can be formed. In this way, a state in which the first thermoelectric conversion film 10, the second thermoelectric conversion film 11, the first electrode 13, the second electrode 14, the first terminal 15, and the second terminal 16 are formed on the upper face of the dummy substrate is formed. In other words, a state in which the thermoelectric conversion circuit module 5 is formed on the upper face of the dummy substrate is formed.

Thereafter, a second heat transfer member 3 in which convex parts 21 to be described later are formed is prepared, and lower end surfaces of the convex parts 21 and an upper end surface of the first electrode 13 are bonded. At this time, as will be described later, it is preferable that the convex part 21 and the first electrode 13 be bonded through an insulating member. Accordingly, a state in which the thermoelectric conversion circuit module 5 and the second heat transfer member 3 formed on the upper face of the dummy substrate are integrated is formed.

Then, after bonding the second heat transfer member 3, the dummy substrate is removed, and the dummy substrate and the thermoelectric conversion circuit module 5 are separated.

In this way, the thermoelectric conversion circuit module 5 combined with the second heat transfer member 3 can be achieved. However, a method of manufacturing the thermoelectric conversion circuit module 5 is not limited to that of this case, and the thermoelectric conversion circuit module 5 may be manufactured using any other method.

The first terminal 15 becomes an electrical start end of the thermoelectric conversion circuit module 5 described above. On the other hand, the second terminal 16 becomes a terminal end of the thermoelectric conversion circuit module 5. The first terminal 15 and second terminal 16 are electrically connected to external circuits not illustrated in the drawing. Accordingly, an electromotive force can be extracted from the thermoelectric conversion device 1 through the first terminal 15 and the second terminal 16.

In addition, as a material of the first terminal 15 and the second terminal 16, for example, a material which has high conductivity is preferable, and a metal material such as copper (Cu), gold (Au), or the like is particularly preferable.

However, the material of the first terminal 15 and the second terminal 16 is not limited to a metal material, and the first terminal 15 and the second terminal 16 may be formed using a material having conductivity.

### (Second Heat Transfer Member and Convex Part)

The second heat transfer member 3 functions as a heat-receiving member of the thermoelectric conversion device 1 and is disposed on the thermoelectric conversion circuit module 5.

The second heat transfer member 3 is a flat plate-shaped member formed in a rectangular shape that is longer in the first direction L1 than in the second direction L2 in plan view and is formed at the size equal to that of the external shape of the entire thermoelectric conversion circuit module 5. In addition, an upper face of the second heat transfer member 3 is formed as a heat-receiving face 20 that is flat over the entire face.

However, the external size of the second heat transfer member 3 is not limited to that of this case and, for example, the second heat transfer member 3 may be formed in a flat plate shape having an external size larger than the thermoelectric conversion circuit module 5 and increase the area of the light receiving face 20.

At portions positioned on a side of the thermoelectric conversion film 2 with respect to the second heat transfer member 3, convex parts (a heat transfer part according to the present disclosure) 21 that transfer heat to/from the second heat transfer member 3 and the thermoelectric conversion film 2 are disposed. In the case of this embodiment, the convex parts 21 transfer heat from the side of the second heat transfer member 3 to the side of the thermoelectric conversion film 2.

A plurality of the convex parts 21 are formed integrally with the second heat transfer member 3, are formed to protrude from the lower face of the second heat transfer member 3 toward the side below, and are formed with a constant space interposed therebetween in the first direction L1.

More specifically, four convex parts 21 correspond to the number of first electrodes 13, are formed with spaces interposed therebetween in the first direction L1, and are disposed to face the first electrodes 13 functioning as hot junctions from the side above. Accordingly, second electrodes 14 functioning as cold junctions are positioned in the middle of the convex parts 21 that are adjacent to each other in the first direction L1.

The convex part 21 is formed in an oblong shape that is long in the second direction L2 in plan view in correspondence with the shape of the first electrode 13. More specifically, the convex part 21 is formed to be longitudinally long over the entire length of the second heat transfer member 3 in the second direction L2 and is formed to be longer than the first electrode 13 in the second direction L2.

However, the length of the convex part 21 in the second direction L2 may be equal to or shorter than the length of the first electrode 13.

A lower end surface of the convex part 21 is formed to be flat. A width of the convex part 21 in the first direction L1 is equal to a width of the first electrode 13 in the first direction L1. However, the width of the convex part 21 in the first direction L1 may be either larger or smaller than the width of the first electrode 13 in the first direction L1.

The convex part 21 configured as described above is thermally bonded to the first electrode 13 in an electrically insulated state with an insulating member which is not illustrated in the drawings therebetween. In addition, it is preferable to bond the lower end surface of the convex part 21 to the upper end surface of the first electrode 13 with an insulating member therebetween in a state as close to being in surface contact as possible. In such a case, the thermal bonding described above can be stably performed, and the second heat transfer member 3 can be stably added.

In addition, the insulating member is formed using a material having a thermal conductivity higher than the thermal conductivity of air and, for example, UV-curable resins, a silicone-based resins, thermally-conductive greases (for example, silicone-based greases, non-silicone-based greases including metal oxidants, and the like), and the like may be used for the material of the insulating member.

Since the plurality of convex parts 21 are formed on the lower face of the second heat transfer member 3, an air gap portion (a first low heat conduction part according to the present disclosure) 22 is disposed between convex parts 21 adjacent to each other in the first direction L1. In the example illustrated in FIG. 3, a space between convex parts 21 that are adjacent to each other in the first direction L1 is formed as a first low heat conduction part (the air gap portion 22). The air gap portion 22 is a space between the lower face of the second heat transfer member 3, the thermoelectric conversion film 2, and the second electrode 14 excluding locations at which the convex parts 21 are formed, in other words, an air layer and has thermal conductivity lower than the thermal conductivity of the convex part 21.

The second heat transfer member 3 is formed using a material having higher thermal conductivity than the thermal conductivity of the air. Accordingly, heat received from the second heat transfer member 3 through the heat-receiving face 20 is transferred to the first electrodes 13 through the convex parts 21 with priority and can be transferred to the first thermoelectric conversion films 10 and the second thermoelectric conversion films 11 through the first electrode 13. In other words, heat received from the second heat transfer member 3 is transferred to the side of the thermoelectric conversion film 2 through the convex parts 21 and the first electrode 13 with priority over transfer to the side of the thermoelectric conversion film 2 through the air gap portions 22 without passing through the convex parts 21

In addition, as a material of the second heat transfer member 3, a material which has a higher thermal conductivity and for which processing of a convex shape such as the convex part 21 or the like can be readily performed, for example, a metal material such as aluminum (Al), copper (Cu), or the like is particularly preferable.

### (First Heat Transfer Member)

The first heat transfer members 4 are members used for dissipating heat transferred from the first electrodes 13 and are disposed under the thermoelectric conversion circuit module 5.

More specifically, four first heat transfer members 4 are disposed in correspondence with the convex parts 21 and are disposed to be positioned below the convex parts 21. More specifically, the first heat transfer members 4 are disposed to be positioned below the convex parts 21 in a state in which the first electrode 13 is interposed therebetween. In other words, four first heat transfer members 4 are formed in correspondence with the number of the convex parts 21 and the first electrodes 13 and are disposed with spaces interposed therebetween in the first direction L1.

The first heat transfer member 4 is formed in an oblong shape that is long in the second direction L2 in plan view in correspondence with the shape of the first electrode 13. More specifically, the first heat transfer member 4 is formed such that a length in the second direction L2 is slightly longer than that of the first electrode 13.

However, the length of the first heat transfer member 4 in the second direction L2 may be equal to or smaller than the length of the first electrode 13.

A width of the first heat transfer member 4 in the first direction L1 is slightly larger than a width of the first electrode 13 in the first direction L1. However, the width of the first heat transfer member 4 in the first direction L1 may be either smaller than the width of the first electrode 13 in the first direction L1 or equal to the width of the first electrode 13 in the first direction L1.

In addition, an upper end surface of the first heat transfer member 4 is formed to be flat.

Similar to the convex parts 21, the first heat transfer members 4 configured as described above, for example, are thermally bonded to the first electrodes 13 through insulating members not illustrated in the drawing. At this time, lower end surfaces of the first electrodes 13 and upper end surfaces of the first heat transfer members 4 can be brought into surface contact through the insulating members, and accordingly, the thermal bonding described above is stably performed, and the first heat transfer members 4 can be stably combined.

As a material of the first heat transfer members 4, a material having higher thermal conductivity than that of the air is preferable, and a material having particularly high thermal conductivity, for example, a metal material such as aluminum (Al), copper (CU), or the like is particularly preferable.

As described above, a plurality of the first heat transfer members 4 are disposed under the first electrodes 13, and an air gap portion (a second low heat conduction part according to the present disclosure) 25 is disposed between the first heat transfer members 4 adjacent to each other in the first direction L1. In the example illustrated in FIG. 3, a gap between the first heat transfer members 4 adjacent to each other in the first direction L1 is set as a second low heat conduction part (air gap portion 25). The air gap portion 25 is configured as a so-called air layer and has lower thermal conductivity than the thermal conductivity of the first heat transfer member 4.

The air gap portion 25 is disposed not only at a middle position of the first heat transfer members 4 adjacent to each other in the first direction L1, in other words, under the second electrode 14 but also under the first thermoelectric conversion film 10 and the second thermoelectric conversion film 11 (to stretch between the first heat transfer members 4 adjacent to each other in the first direction L1).

### (Operation of Thermoelectric Conversion Device)

Next, the operation of the thermoelectric conversion device 1 configured as described above will be described.

First, in the thermoelectric conversion device 1, thermoelectric conversion is performed using a Seebeck effect of the first thermoelectric conversion film 10 and the second thermoelectric conversion film 11. The following Equation (1) is an equation relating to the Seebeck effect.

E=S×|ΔT| Equation (1)

E(V) in Equation (1) is an electric field (electromotive force) achieved through thermoelectric conversion and, as represented in Equation (1) and is defined using a Seebeck coefficient S(V/K) that is a material constant of the first thermoelectric conversion film 10 or the second thermoelectric conversion film 11 and a temperature difference ΔT(K) between the front end portion 10b or 11b and the rear end portion 10a or 11a of the first thermoelectric conversion film 10 or the second thermoelectric conversion film 11.

According to the thermoelectric conversion device 1 of this embodiment, as denoted using a dotted-line arrow illustrated in FIG. 3, heat received from the second heat transfer member 3 through the heat-receiving face 20 can be transferred to the first electrodes 13 through the convex parts 21 with priority, and heat can be transferred from the first electrode 13 to the rear end portion 10a of the first thermoelectric conversion film 10 and the front end portion 11b of the second thermoelectric conversion film 11.

For this reason, in the first thermoelectric conversion film 10, a temperature difference can be caused to occur between the rear end portion 10a positioned on the side of the first electrode 13 that is a hot junction (an end portion of the hot junction side) and the front end portion 10b positioned on the side of the second electrode 14 that is a cold junction (an end portion of the cold junction side). Similarly, in the second thermoelectric conversion film 11, a temperature difference can be caused to occur between the front end portion 11b positioned on the side of the first electrode 13 that is a hot junction (an end portion of the hot junction side) and the rear end portion 11a positioned on the side of the second electrode 14 that is a cold junction (an end portion of the cold junction side).

Accordingly, an electromotive force based on the Seebeck effect can be generated in each of the first thermoelectric conversion film 10 and the second thermoelectric conversion film 11.

Particularly, since the first thermoelectric conversion film 10 and the second thermoelectric conversion film 11 are electrically connected in series, an electromotive force achieved by summing electromotive forces generated from the first thermoelectric conversion film 10 and the second thermoelectric conversion film 11 can be achieved through the first terminal 15 and the second terminal 16, and an amount of generated power according to the number of thermoelectric conversion films 2 can be achieved.

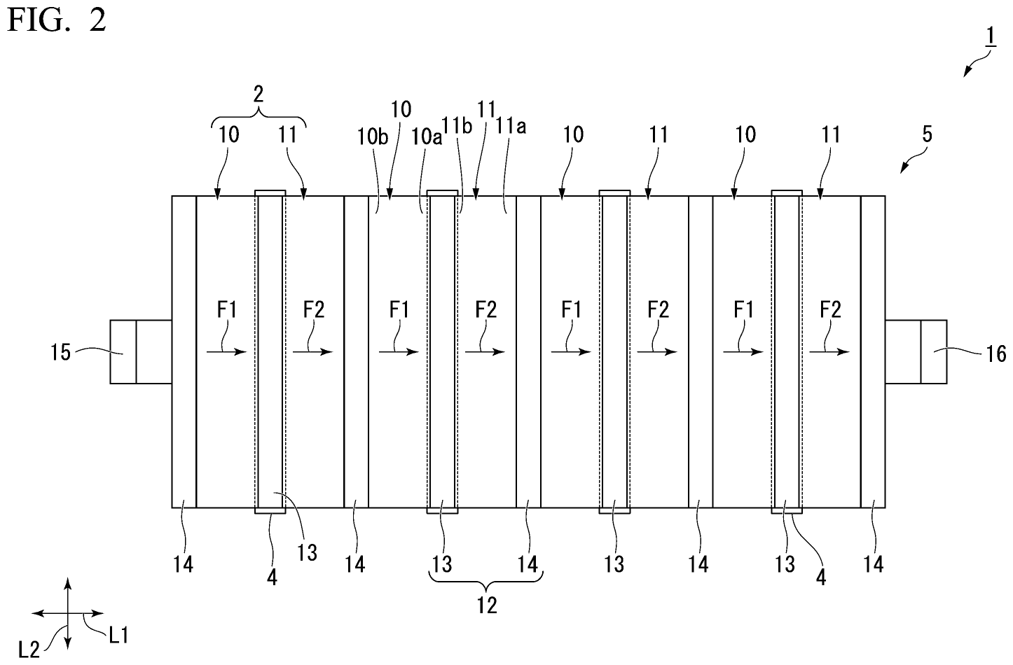

Details of the electromotive force described above will now be described. Since the first thermoelectric conversion film 10 is an n-type semiconductor, a current flows from the side of the second electrode 14 that becomes a cold junction to the side of the first electrode 13 that becomes a hot junction as represented using an arrow F1 illustrated in FIG. 2. On the other hand, since the second thermoelectric conversion film 11 is a p-type semiconductor, a current flows from the side of the first electrode 13 that becomes a hot junction to the side of the second electrode 14 that becomes a cold junction as represented using an arrow F2 illustrated in FIG. 2.

Accordingly, in the first thermoelectric conversion film 10 and the second thermoelectric conversion film 11, electromotive forces of the same direction can be generated, and, as described above, electromotive forces generated in a plurality of first thermoelectric conversion films 10 and a plurality of second thermoelectric conversion films 11 can be extracted through the first terminal 15 and the second terminal 16 as a sum thereof.

Meanwhile, by disposing the first heat transfer members 4 under the first electrodes 13, the first heat transfer member 4 faces the convex part 21 in the thickness direction with the thermoelectric conversion circuit module 5 interposed therebetween. Accordingly, in accordance with a heat dissipation or cooling effect of the first heat transfer member 4, heat transferred from the convex part 21 to the first thermoelectric conversion film 10 and the second thermoelectric conversion film 11 through the first electrode 13, as denoted using a dotted-line arrow illustrated in FIG. 3, is easily released to the side of the first heat transfer member 4 through the first electrode 13 rather than the heat being conducted from the hot junction side (the first electrode 13 side) to the cold junction side (the second electrode 14 side) inside the first thermoelectric conversion film 10 and the second thermoelectric conversion film 11.

Accordingly, in a case in which the amount heat received from the second heat transfer member 3 is large, a part of the heat can be released through the first heat transfer member 4, and excessive heat can be inhibited from flowing into the side of the first thermoelectric conversion film 10 and the side of the second thermoelectric conversion film 11.

Accordingly, a decrease in a temperature difference occurring between the hot junction side and the cold junction side in the first thermoelectric conversion film 10 and the second thermoelectric conversion film 11 can be inhibited, and accordingly, a large amount of generated power can be achieved.

Particularly, since the air gap portion 25 that is an air layer is disposed between the first heat transfer members 4 adjacent to each other in the first direction L1, it can be caused to be difficult for heat transferred to the first heat transfer member 4 to be transferred in the first direction L1 through the air gap portion 25.

Accordingly, as described above, a decrease in the temperature difference between the hot junction side and the cold junction side in the first thermoelectric conversion film 10 and the second thermoelectric conversion film 11 can be inhibited, whereby a large amount of generated power can be achieved.

In addition, since the air gap portion 25 is disposed not only under the second electrode 14 but also under the first thermoelectric conversion film 10 and the second thermoelectric conversion film 11, it is difficult for heat transferred to the first heat transfer member 4 to spread to the in-plane direction of the virtual plane M through the air gap portion 25, and it is difficult for the heat to be transferred to the side of the front end portion 10b of the first thermoelectric conversion film 10 and the side of the rear end portion 11a of the second thermoelectric conversion film 11. Accordingly, the operations and effects described above can be successfully achieved remarkably.

As described above, according to the thermoelectric conversion device 1 of this embodiment, by using the first heat transfer members 4 and the air gap portions 25, excessive heat can be inhibited from flowing into the side of the first thermoelectric conversion film 10 and the side of the second thermoelectric conversion film 11, and a large amount of generated power can be achieved.

Accordingly, the high-quality and high-performance thermoelectric conversion device 1 having a superior thermoelectric conversion efficiency can be configured.

### (Modified Example of First Embodiment)

In the first embodiment described above, although the air gap portions 25 that are air layers have been described as a second low heat conduction part as an example, the second low heat conduction part is not limited thereto. For example, the second low heat conduction part may be a low heat conduction member formed using a material having lower thermal conductivity than the thermal conductivity of the first heat transfer member 4. As a material of the low heat conduction member, for example, aluminum oxide (Al₂O₃), polytetrafluoroethylene (PTFE), a polyimide resin, or the like may be used.

In addition, a configuration using the low heat conduction member as the second low heat conduction part may be employed in any other embodiment other than the first embodiment.

### Second Embodiment

Next, a thermoelectric conversion device according to a second embodiment of the present disclosure will be described with reference to the drawings.

In the second embodiment, the same reference signs will be assigned to the same parts as the constituent elements of the first embodiment, and description thereof will be omitted.

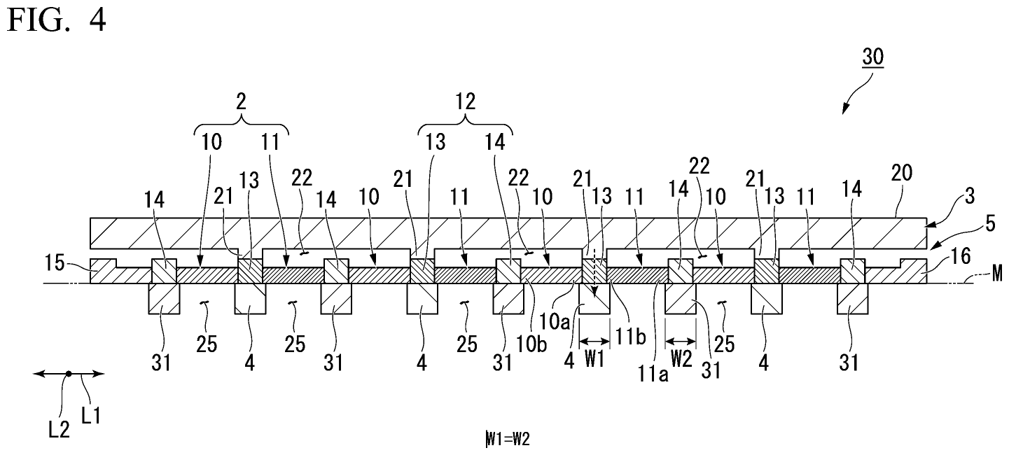

As illustrated in FIG. 4, a thermoelectric conversion device 30 according to this embodiment includes third heat transfer members (a third heat transfer member according to the present disclosure) 31 that are disposed under a thermoelectric conversion circuit module 5 and have higher thermal conductivity than that of air gap portions 25 (in other words, higher thermal conductivity than that of the air).

In the thermoelectric conversion device 30 according to this embodiment, the points described above are mainly different from the first embodiment, and the other components are the same as those according to the first embodiment. Furthermore, also in this embodiment, similar to the first embodiment, a case in which heat is transferred from a side of a second heat transfer member 3 to a side of a thermoelectric conversion film 2 will be described as an example.

### (Third Heat Transfer Member)

The third heat transfer member 31 is a member that is used for cooling an end portion of the thermoelectric conversion film 2 on the cold junction side (in other words, a front end portion 10b of a first thermoelectric conversion film 10 and a rear end portion 11a of the second thermoelectric conversion film 11) or dissipating heat from an end portion of the thermoelectric conversion film 2 on the cold junction side and are positioned at a middle position of the first heat transfer member 4 at which they are adjacent to each other in the first direction L1.

In addition, in this embodiment, the third heat transfer member 31 is disposed not only at a middle position of the first heat transfer members 4 that are adjacent to each other in the first direction L1 but also under a second electrode 14 that is positioned on the front-most side and the rear-most side. In other words, five third heat transfer members 31 are disposed in correspondence with the number of second electrodes 14 such that they are disposed under all the second electrodes 14 and are disposed with spaces interposed therebetween in the first direction L1.

The third heat transfer member 31 is formed to be vertically long in the second direction L2 in plan view in correspondence with the shape of the second electrode 14. At this time, a length of the third heat transfer member 31 in the second direction L2 may be equal to a length of the second electrode 14 or larger or smaller than the length of the second electrode 14.

In addition, in this embodiment, a width W2 of the third heat transfer member 31 in the first direction L1 is equal to a width W1 of a first heat transfer member 4 in the first direction L1 and is slightly larger than a width of the second electrode 14 in the first direction L1.

However, the width W2 of the third heat transfer member 31 in the first direction L1 may be smaller than the width of the second electrode 14 in the first direction L1 or equal to the width of the second electrode 14 in the first direction L1.

In addition, the upper end surface of the third heat transfer member 31 is formed to be flat.

The third heat transfer member 31 configured as described above, for example, similar to the first heat transfer member 4, is thermally bonded to the second electrode 14 through an insulating member not illustrated in the drawing. At this time, since the lower end surface of the second electrode 14 and the upper end surface of the third heat transfer member 31 can be brought into surface contact through an insulating member, the thermal bonding described above is stably performed, and the third heat transfer member 31 can be stably combined.

In addition, as a material of the third heat transfer member 31, a material having higher thermal conductivity than the thermal conductivity of the air is preferable, and a material having particularly high thermal conductivity, for example, a metal material such as copper (Cu), gold (Au), or the like is particularly preferable.

As described above, since the third heat transfer members 31 are disposed, an air gap portion 25 is disposed between the first heat transfer member 4 and the third heat transfer member 31 that are adjacent to each other in the first direction L1. In the example illustrated in FIG. 4, an area between the first heat transfer member 4 and the third heat transfer member 31 that are adjacent to each other in the first direction L1 is configured as a second low heat conduction part (the air gap portion 25). In other words, the air gap portion 25 according to this embodiment is disposed to be positioned under the first thermoelectric conversion film 10 and the second thermoelectric conversion film 11. Also in such a case, the air gap portion 25 is disposed between the second heat transfer members adjacent to each other in the first direction L1.

### (Operation of Thermoelectric Conversion Device)

According to the thermoelectric conversion device 30 of this embodiment configured as described above, similar to the first embodiment, in accordance with a heat dissipation or cooling effect of the first heat transfer member 4, heat transferred from the convex parts 21 to the first thermoelectric conversion films 10 and the second thermoelectric conversion films 11 through the first electrodes 13, as denoted using a dotted-line arrow illustrated in FIG. 4, is easily released to the side of the first heat transfer member 4 through the first electrodes 13 rather than the heat being conducted from the hot junction side (the first electrode 13 side) to the cold junction side (the side of the second electrode 14) inside the first thermoelectric conversion film 10 and the second thermoelectric conversion film 11.

In addition, simultaneously with this, in accordance with a heat dissipation or cooling effect of the third heat transfer members 31, the front end portion 10b of the first thermoelectric conversion film 10 and the rear end portion 11a of the second thermoelectric conversion film 11 can be cooled through the third heat transfer member 31.

In this way, both a heat dissipation or cooling effect using the first heat transfer member 4 and a heat dissipation or cooling effect using the third heat transfer member 31 can be used, and accordingly, it is difficult to be influenced by the amount of heat received from the second heat transfer member 3, and a temperature difference between the hot junction side and the cold junction side in the first thermoelectric conversion film 10 and the second thermoelectric conversion film 11 can be stably increased. Accordingly, a large amount of generated power can be achieved more stably.

### (Modified Example of Second Embodiment)

In the second embodiment described above, although the width W1 of the first heat transfer member 4 in the first direction L1 and the width W2 of the third heat transfer member 31 in the first direction L1 are configured to be the same, the widths are not limited to those of such a case and may be appropriately changed.

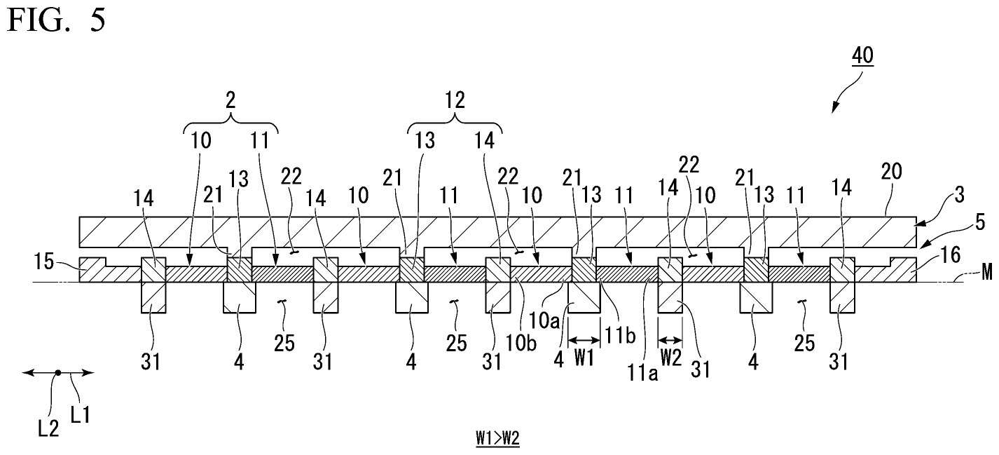

For example, as illustrated in FIG. 5, the width W1 of the first heat transfer member 4 in the first direction L1 may be formed to be larger than the width W2 of the third heat transfer member 31 in the first direction L1.

In the thermoelectric conversion device 40 configured in this way, since a heat dissipation or cooling effect of the first heat transfer member 31 is successfully achieved more effectively than a heat dissipation or cooling effect of the third heat transfer member 4. Accordingly, particularly in a case in which the amount of heat received from the second heat transfer member 3 is large, a part of the heat can be easily released to the outside through the first heat transfer member 4. For this reason, flow of a large amount of heat into the side of the first thermoelectric conversion film 10 and the second thermoelectric conversion film 11 side can be effectively inhibited.

Accordingly, also in a case in which the amount of heat received from the second heat transfer member 3 is particularly large, it is easy to secure a temperature difference between the hot junction side and the cold junction side in the first thermoelectric conversion film 10 and the second thermoelectric conversion film 11, and a large amount of generated power can be achieved.

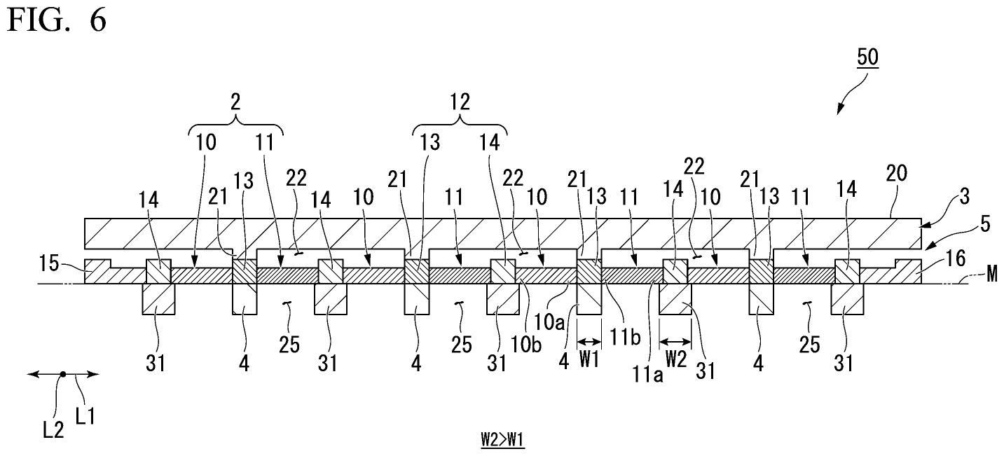

In addition, as illustrated in FIG. 6, the width W2 of the third heat transfer member 31 in the first direction L1 may be formed to be larger than the width W1 of the first heat transfer member 4 in the first direction L1.

In the thermoelectric conversion device 50 configured in this way, the heat dissipation or cooling effect of the third heat transfer member 31 can be successfully achieved more effectively than the heat dissipation or cooling effect of the first heat transfer member 4. Accordingly, by using the heat dissipation or cooling effect of the third heat transfer member 31, the cold junction side of the first thermoelectric conversion film 10 and the second thermoelectric conversion film 11 (in other words, the side of the front end portion 10b of the first thermoelectric conversion film 10 and the side of the rear end portion 11a of the second thermoelectric conversion film 11) can be easily cooled effectively.

Accordingly, it is easy to secure a temperature difference between the hot junction side and the cold junction side in the first thermoelectric conversion film 10 and the second thermoelectric conversion film 11, and a large amount of generated power can be achieved.

### Third Embodiment

Next, a thermoelectric conversion device according to a third embodiment of the present disclosure will be described with reference to the drawings.

In the third embodiment, the same reference signs will be assigned to parts which are the same as constituent elements of the second embodiment, and description thereof will be omitted.

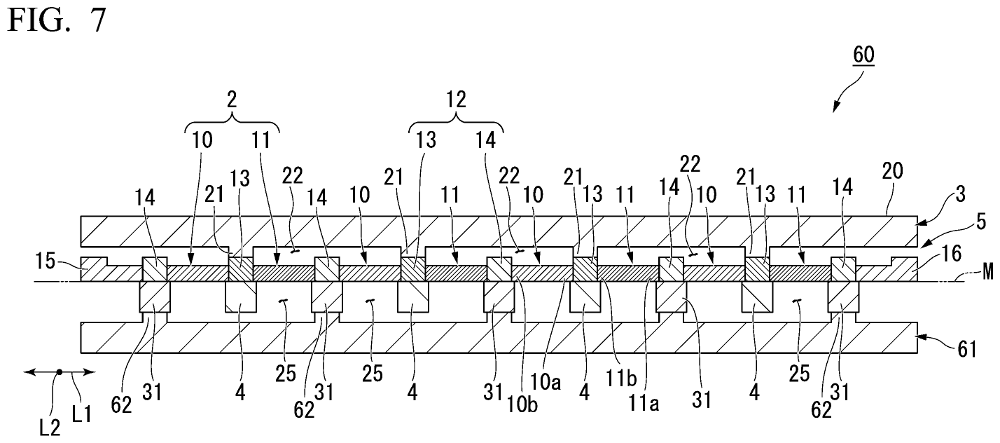

As illustrated in FIG. 7, a thermoelectric conversion device 60 according to this embodiment includes a flat plate-shaped fourth heat transfer member (a fourth heat transfer member according to the present disclosure) 61 that is disposed on a side below the first heat transfer members 4 and third heat transfer members 31.

The thermoelectric conversion device 60 according to this embodiment is essentially different from the second embodiment in terms of the points stated above, but its configuration is otherwise the same as that according to the second embodiment. Furthermore, also in this embodiment, similar to the second embodiment, a case in which heat is transferred from the side of the second heat transfer member 3 to the side of the thermoelectric conversion film 2 will be described as an example.

### (Fourth Heat Transfer Member)

The fourth heat transfer member 61 is bonded to third heat transfer members 31 through convex parts 62 to be described later from the side below in a state of not being in a contact with the first heat transfer members 4. On the other hand, the fourth heat transfer member 61 is thermally bonded to the third heat transfer member 31 and transfers heat from/to thermoelectric conversion films 2 through the third heat transfer members 31 rather than through the first heat transfer members 4. In other words, heat is transferred to the fourth heat transfer member 61 through the third heat transfer members 31 rather than the first heat transfer members 4. For this reason, the fourth heat transfer member 61 can dissipate heat transferred through the third heat transfer members 31 or allow cooling.

The fourth heat transfer member 61 is formed in a rectangular shape that is longer in the first direction L1 than in the second direction L2 in plan view in correspondence with the shape of the entire thermoelectric conversion circuit module 5. The fourth heat transfer member 61 is formed with a size equal to that of the external shape of the thermoelectric conversion circuit module 5.

However, the shape and the size are not limited to those of this case, and the fourth heat transfer member 61, for example, may be formed in a flat plate shape of which the external size is larger than that of the thermoelectric conversion circuit module 5.

In this embodiment, convex parts 62 are formed integrally with the fourth heat transfer member 61 on an upper face of the fourth heat transfer member 61. The convex parts 62 are disposed to protrude from an upper face of the fourth heat transfer member 61 to the side above with a constant space interposed therebetween in the first direction L1.

More specifically, five convex parts 62 are formed in correspondence with the third heat transfer members 31 and are disposed to face these third heat transfer members 31 from the side below. As described above, the convex parts 62 are bonded to the third heat transfer members 31, whereby the fourth heat transfer member 61 is combined with the third heat transfer members 31.

In the example illustrated in FIG. 7, although the convex parts 62 are directly bonded to the third heat transfer members 31, the convex parts 62 may be bonded to the third heat transfer members 31 through other members such as paste-like materials or the like. As a specific material of the paste-like material, for example, there is heat conductive grease including a highly heat-conductive material such as silver (Ag) or diamond (C) as a filler.

In this way, since the fourth heat transfer member 61 is bonded to the third heat transfer members 31 through the convex parts 62, a gap (an air layer) is secured between the fourth heat transfer member 61 and the first heat transfer members 4 in the thickness direction. Accordingly, as described above, the fourth heat transfer member 61 is in a state not being in contact with the first heat transfer member 4.

In addition, it is preferable that the shape of the fourth heat transfer member 61 be a shape that is preferable for heat dissipation or cooling. For example, it is preferable that the fourth heat transfer member 61 have a flow passage for air cooling or water cooling inside thereof. In addition, it is preferable that the fourth heat transfer member 61, for example, have a pin shape used for heat exchange on a face side opposite to a face on the side of the third heat transfer member 31.

Furthermore, as a material of the fourth heat transfer member 61, similar to the second heat transfer member 3, a material which has high thermal conductivity and for which a convex shape such as the convex parts 62 or the like can be easily processed, for example, a metal material such as aluminum (Al), copper (CU), or the like is particularly preferable.

### (Operation of Thermoelectric Conversion Device)

According to the thermoelectric conversion device 60 of this embodiment configured as described above, in addition to operations and effects similar to those according to the second embodiment being successfully achieved, the following operations and effects can be obtained more successfully.

In other words, by using a heat dissipation or cooling effect of the fourth heat transfer member 61, the cold junction sides of the first thermoelectric conversion film 10 and the second thermoelectric conversion film 11 (in other words, the side of the front end portion 10b of the first thermoelectric conversion film 10 and the side of the rear end portion 11a of the second thermoelectric conversion film 11) can be further cooled through the third heat transfer members 31 and the fourth heat transfer member 61.

Accordingly, a temperature difference between the hot junction side and the cold junction side in the first thermoelectric conversion film 10 and the second thermoelectric conversion film 11 can be effectively increased, and a large amount of generated power can be obtained. Particularly, since the fourth heat transfer member 61 is formed in a flat-plate shape, for example, a large area for a lower face functioning as a heat dissipation face or a cooling face can be secured. Accordingly, the operations and the effects described above can be successfully achieved more effectively.

In addition, since one common fourth heat transfer member 61 can be thermally bonded to a plurality of third heat transfer members 31, each of the cold junction sides of the first thermoelectric conversion film 10 and the second thermoelectric conversion film 11 is easily cooled uniformly with a small deviation through each of the third heat transfer members 31.

### (Modified Example of Third Embodiment)

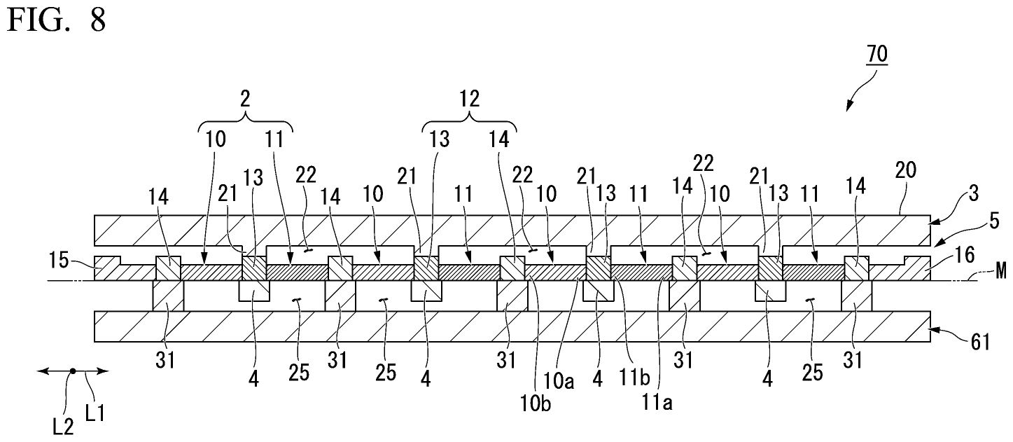

In the third embodiment described above, although the convex parts 62 are disposed in the fourth heat transfer member 61, the convex parts 62 are not essential and may not be included. For example, as illustrated in FIG. 8, there may be a configuration in which a thermoelectric conversion device 70 includes a fourth heat transfer member 61 of which the upper face is a flat face.

In such a case, for example, the thickness of the first heat transfer member 4 may be smaller than the thickness of the third heat transfer member 31. In other words, a length of the first heat transfer member 4 directed from the first electrode 13 toward the fourth heat transfer member 61 in the thickness direction (a vertical direction perpendicular to the virtual plane M) may be smaller than a length of the third heat transfer member 31 directed from the second electrode 14 toward the fourth heat transfer member 61 in the thickness direction (a vertical direction perpendicular to the virtual plane M).

In this way, heat is transferred to the fourth heat transfer member 61 through the third heat transfer members 31 rather than the first heat transfer members 4.

In the example illustrated in FIG. 8, although the fourth heat transfer member 61 is directly bonded to the third heat transfer members 31, the fourth heat transfer member 61 may be bonded to the third heat transfer members 31 through other members such as the paste-like materials described above or the like.

Also in the case of the thermoelectric conversion device 70 configured in such a way, operations and effects similar to those of the third embodiment can be successfully achieved.

### Fourth Embodiment

Next, a thermoelectric conversion device according to a fourth embodiment of the present disclosure will be described with reference to the drawings.

In the fourth embodiment, the same reference signs will be assigned to the same parts as the constituent elements of the first embodiment, and description thereof will be omitted.

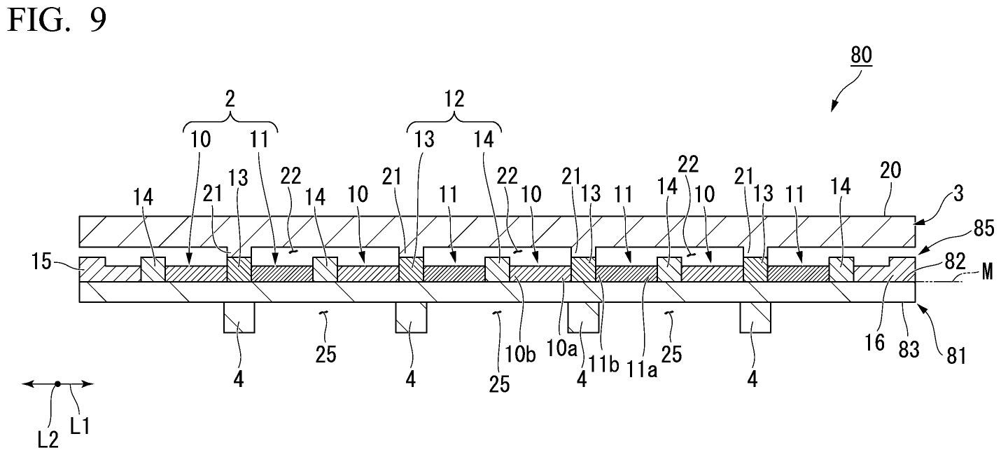

As illustrated in FIG. 9, a thermoelectric conversion device 80 according to this embodiment includes a substrate 81 that includes a first principal surface (a first surface according to the present disclosure) 82 and a second principal surface (a second surface according to the present disclosure) 83 facing each other in the thickness direction and is disposed along a virtual plane M

In the thermoelectric conversion device 80 according to this embodiment, the points described above are mainly different from the first embodiment, and the other components are the same as those according to the first embodiment. Furthermore, also in this embodiment, similar to the first embodiment, a case in which heat is transferred from the side of the second heat transfer member 3 to the side of the thermoelectric conversion film 2 will be described as an example.

### (Substrate)

The substrate 81 has the first principal surface 82 disposed toward the side above, has the second principal surface 83 disposed toward the side below, and is formed in a rectangular shape that is longer in the first direction L1 than in the second direction L2 in plan view in correspondence with the shape of the second heat transfer member 3. The substrate 81 has an external shape of which the size is equal to that of the external shape of the second heat transfer member 3. Although the thickness of the substrate 81 is not particularly limited, in the example illustrated in FIG. 9, the thickness of the substrate 81 is formed to be larger than the thickness of the thermoelectric conversion film 2 and is smaller than the thickness of the second heat transfer member 3.

First thermoelectric conversion films 10, second thermoelectric conversion films 11, first electrodes 13, second electrodes 14, a first terminal 15, and a second terminal 16 are formed on the side of the first principal surface 82 of the substrate 81.

However, the configuration is not limited to this case, and, for example, integration of the entire thermoelectric conversion circuit module 5 according to the first embodiment that is in a state of being placed on the first principal surface 82 of the substrate 81 may be employed. In any case, the first thermoelectric conversion films 10, the second thermoelectric conversion films 11, the first electrodes 13, the second electrodes 14, the first terminal 15, and the second terminal 16 may be disposed on the side of the first principal surface 82 of the substrate 81.

In addition, in this embodiment, the first thermoelectric conversion films 10, the second thermoelectric conversion films 11, the first electrodes 13, the second electrodes 14, the first terminal 15, the second terminal 16, and the substrate 81 configure a thermoelectric conversion circuit module 85.

The first heat transfer members 4 are disposed on the side of the second principal surface 83 of the substrate 81 and are bonded to the second principal surface 83. In this way, the first heat transfer members 4 are disposed to face the second electrodes 14 and the convex parts 21 in the thickness direction with the substrate 81 interposed therebetween. In other words, the substrate 81 is disposed between the first thermoelectric conversion film 10 and the second thermoelectric conversion film 11 and the first heat transfer member 4 in a state in which the first principal surface 82 is directed toward the first thermoelectric conversion film 10 and the side of the second thermoelectric conversion film 11, and the second principal surface 83 is directed toward the side of the first heat transfer member 4.

As one example of the substrate 81, for example, there is a high-resistance silicon (Si) substrate of which a sheet resistance is equal to or higher than 10Ω. In addition, although the resistance value is not limited to being equal to or higher than 10Ω, it is preferable to use a high-resistance substrate of which a sheet resistance is equal to or higher than 10Ω from the point of view of preventing formation of an electrical short circuit between the thermoelectric conversion films 2.

However, the substrate 81 is not limited to a high-resistance silicon substrate, and, for example, the substrate 81 may be a high-resistance SOI substrate having an oxide insulating layer inside the substrate, any other high-resistance single-crystalline substrate, or a ceramic substrate. In addition, a low-resistance substrate of which sheet resistance is equal to or lower than 10Ω may be used as the substrate 81. In such a case, for example, a high-resistance material may be disposed between a surface of the low-resistance substrate and the thermoelectric conversion film 2.

### (Operation of Thermoelectric Conversion Device)

According to the thermoelectric conversion device 80 of this embodiment configured as described above, in addition to successful acquisition of operations and effects similar to those according to the first embodiment, the following operations and effects can be further achieved successfully.

In other words, since the substrate 81 can be used as a support substrate, the first thermoelectric conversion films 10, the second thermoelectric conversion films 11, the first electrodes 13, the second electrodes 14, the first terminal 15, the second terminal 16, and the first heat transfer member 4 can be combined in a more stable state than that according to the first embodiment. Accordingly, operations and effects similar to those according to the first embodiment can be successfully achieved more stably.

In addition thereto, by including the substrate 81, it becomes easy to increase the rigidity of the thermoelectric conversion circuit module 85, and improvement of the rigidity of the entire thermoelectric conversion device 80 can be achieved. Accordingly, for example, a high-quality thermoelectric conversion device 80 having resistance to unintended deformation such as membrane stress, bending, deflection, and the like of the thermoelectric conversion film 2 can be configured. Accordingly, the utility of a product can be further improved.

In addition, also in the case of this embodiment, by forming the thickness of the substrate 81 to be small, conduction of heat inside the substrate 81 can be suppressed, and accordingly, although the substrate 81 is included, operations and effects similar to those according to the first embodiment can be successfully achieved.

### Fifth Embodiment

Next, a thermoelectric conversion device according to a fifth embodiment of the present disclosure will be described with reference to the drawings.

In the fifth embodiment, the same reference signs will be assigned to the same parts as the constituent elements of the fourth embodiment, and description thereof will be omitted.

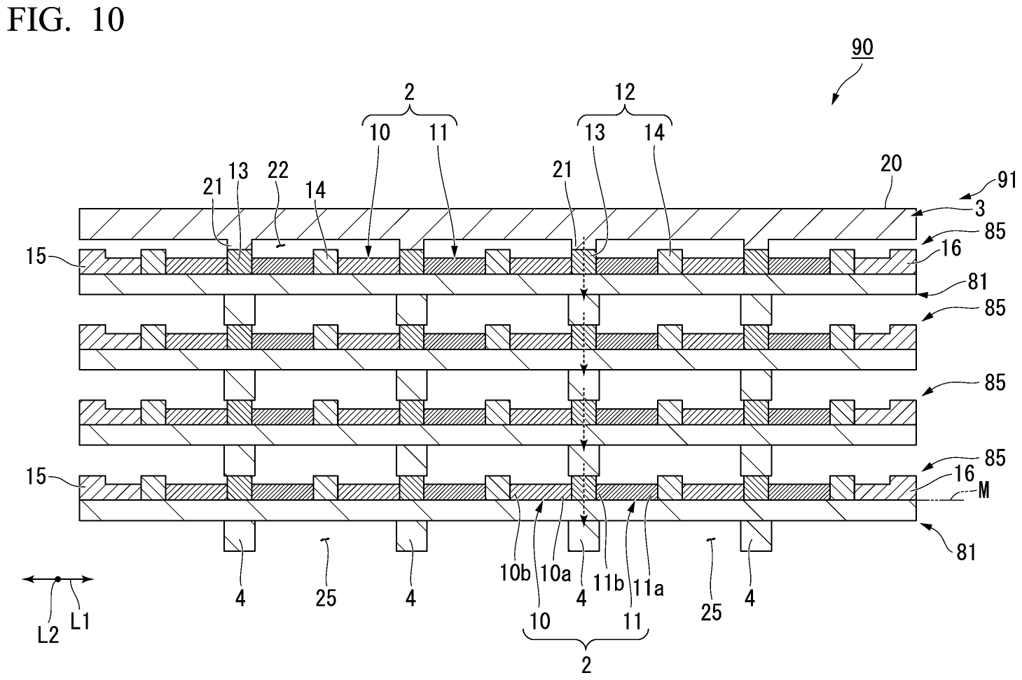

As illustrated in FIG. 10, a thermoelectric conversion device 90 according to this embodiment includes a thermoelectric conversion module 91 in which thermoelectric conversion circuit modules 85 and first heat transfer member 4 are piled up in multiple layers in the thickness direction.

In the thermoelectric conversion device 90 according to this embodiment, inclusion of the thermoelectric conversion module 91 is mainly different from the fourth embodiment, and the configurations of the first thermoelectric conversion films 10, the second thermoelectric conversion films 11, the first electrodes 13, the second electrodes 14, the first terminal 15, the second terminal 16, the substrate 81, and the first heat transfer member 4 are the same as those according to the fourth embodiment.

Furthermore, in this embodiment, the thermoelectric conversion module 91 in which thermoelectric conversion circuit modules 85 and first heat transfer members 4 are piled up in four layers is configured. However, the thermoelectric conversion module 91 is not limited to four layers and may have a multi-layer structure in which two or more layers are piled up.

Furthermore, also in this embodiment, similar to the fourth embodiment, a case in which heat is transferred from the side of the second heat transfer member 3 to the side of the thermoelectric conversion film 2 positioned in an uppermost layer (the fourth layer) will be described as an example.

The second heat transfer member 3 is disposed on the thermoelectric conversion circuit module 85 positioned in an uppermost layer (the fourth layer) in the thermoelectric conversion module 91 and is bonded to the first electrode 13 of this thermoelectric conversion circuit module 85, similar to the fourth embodiment, through convex parts 21 and insulating members not illustrated in the drawing.

In the thermoelectric conversion module 91, first thermoelectric conversion films 10 and second thermoelectric conversion films 11 of the thermoelectric conversion circuit module 85 positioned in any one of layers other than the uppermost layer (the first to third layers) are bonded to the first heat transfer members 4 positioned on the layer above thereof through the first electrodes 13. In this case, the first heat transfer members 4, similar to the convex parts 21, may be bonded to the first electrodes 13 through insulating members not illustrated in the drawing.

For example, the first thermoelectric conversion films 10 and the second thermoelectric conversion films 11 of the thermoelectric conversion circuit module 85 positioned in a first layer (the lowermost layer) are bonded to the first heat transfer members 4 positioned in the second layer through the first electrodes 13 from the side below.

Accordingly, the thermoelectric conversion films 2 positioned in any one of layers other than the uppermost layer (the first to third layers) in the thermoelectric conversion module 91 are thermally bonded to the first heat transfer members 4 positioned in the layer above thereof through the first electrodes 13 and transfer heat to/from the thermoelectric conversion films 2 positioned in the layer above thereof through the first heat transfer members 4 positioned in the layer above thereof rather than through air gap portions 25 positioned in the layer above thereof. In other words, heat is transferred to the thermoelectric conversion films 2 positioned in any one of layers other than the uppermost layer (the first layer to the third layer) through the first heat transfer members 4 positioned in the layer above thereof rather than through air gap portions 25 positioned in the layer above thereof.

### (Operation of Thermoelectric Conversion Device)

According to the thermoelectric conversion device 90 of this embodiment configured as described above, in addition to successful acquisition of operations and effects similar to those according to the fourth embodiment, the following operations and effects can be further achieved successfully.

In other words, since the thermoelectric conversion module 91 is included, for example, heat dissipated through the first heat transfer members 4 positioned in the fourth layer, similar to a dotted-line arrow illustrated in FIG. 10, can be transferred to the first electrodes 13 of the third layer positioned on the layer below thereof and can be transferred to hot junction sides (in other words, the side of the rear end portion 10a of the first thermoelectric conversion film 10 and the side of the front end portion 11b of the second thermoelectric conversion film 11) in the first thermoelectric conversion film 10 and the second thermoelectric conversion film 11 positioned in the third layer through these first electrodes 13.

In this way, the dissipated heat can be effectively used, and power generation in the thermoelectric conversion film 2 of each layer can be achieved. Accordingly, a large amount of generated power can be achieved with a high efficiency.

### (Modified Example of Fifth Embodiment)

In the fifth embodiment described above, although a case in which the thermoelectric conversion circuit module 85 including the substrate 81 and the first heat transfer member 4 are piled up in multiple layers has been described as an example, the substrate 81 is not essential and thus may not be included. For example, a configuration in which the thermoelectric conversion circuit module 5 and the first heat transfer member 4 according to the first embodiment are piled up in multiple layers may be employed. Also in such a case, similar operations and effects may be successfully achieved.

However, in a case in which the substrate 81 is included as in the fifth embodiment, the entire rigidity can be easily improved, which is preferable.

### Sixth Embodiment

Next, a thermoelectric conversion device according to a sixth embodiment of the present disclosure will be described with reference to the drawings.

In the sixth embodiment, the same reference signs will be assigned to the same parts as the constituent elements of the fifth embodiment, and description thereof will be omitted.

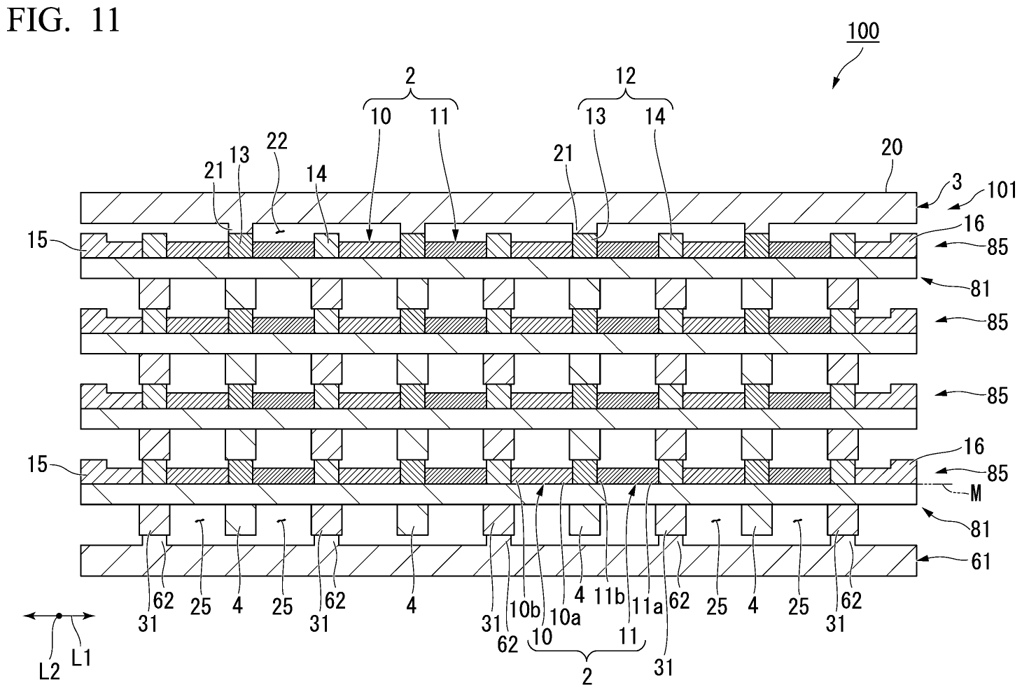

As illustrated in FIG. 11, a thermoelectric conversion device 100 according to this embodiment includes a thermoelectric conversion module 101 in which a thermoelectric conversion circuit module 85, a first heat transfer member 4, and the third heat transfer member 31 according to the second embodiment are piled up in the thickness direction in multiple layers is included. However, the third heat transfer members 31 according to this embodiment are bonded to a lower face of the substrate 81 of each layer and are disposed to face the second electrodes 14 in the thickness direction with the substrate 81 interposed therebetween.

In addition, the thermoelectric conversion device 100 according to this embodiment includes the fourth heat transfer member 61 according to the third embodiment under the first heat transfer member 4 and the third heat transfer member 31 positioned in the lowermost layer (the first layer).

In the thermoelectric conversion device 100 according to this embodiment, the points described above are mainly different from the fifth embodiment, and the other components are the same as those according to the fifth embodiment.

Furthermore, also in this embodiment, similar to the fifth embodiment, a case in which heat is transferred from the side of the second heat transfer member 3 to the side of the thermoelectric conversion film 2 positioned in the uppermost layer (the fourth layer) will be described as an example.

In the thermoelectric conversion module 101, the first thermoelectric conversion film 10 and the second thermoelectric conversion film 11 of the thermoelectric conversion circuit module 85 positioned in any one of layers other than the uppermost layer (the fourth layer) are bonded to the first heat transfer member 4 positioned on the layer above thereof through the first electrode 13 and are bonded to the third heat transfer member 31 positioned in the layer above thereof through the second electrode 14. In this case, the first heat transfer member 4, similar to the convex part 21, may be bonded to the first electrode 13 through an insulating member not illustrated in the drawing, and, similarly, the third heat transfer member 31 may be bonded to the second electrode 14 through an insulating member not illustrated in the drawing.

Accordingly, in the thermoelectric conversion module 101, the thermoelectric conversion film 2 positioned in any one of layers other than the uppermost layer (the first to third layers) is thermally bonded to the first heat transfer member 4 and the third heat transfer member 31 positioned in the layer above thereof through the first electrode 13 and the second electrode 14 and transfers heat from/to the thermoelectric conversion film 2 positioned in the layer above thereof through the first heat transfer member 4 and the third heat transfer member 31 positioned in the layer above thereof rather than through the air gap portion 25 positioned in the layer above thereof. In other words, heat is transferred to the thermoelectric conversion film 2 positioned in any one of layers other than the uppermost layer (the first layer to the third layer) through the first heat transfer member 4 and the third heat transfer member 31 positioned in the layer above thereof rather than the air gap portion 25 positioned in the layer above thereof.

In addition, the fourth heat transfer member 61 is bonded to the third heat transfer members 31 positioned in the lowermost layer (the first layer) through the convex parts 62 in the thermoelectric conversion module 101. In the example illustrated in FIG. 11, although the convex part 62 is directly bonded to the third heat transfer member 31, the convex part 62 may be bonded to the third heat transfer member 31 through another member such as the paste-like material described above or the like.

Accordingly, the fourth heat transfer member 61 is thermally bonded to the third heat transfer members 31 positioned in the lowermost layer (the first layer) and transfers heat to/from the thermoelectric conversion film 2 positioned in the lowermost layer through the third heat transfer members 31 positioned in the lowermost layer rather than through the first heat transfer members 4 positioned in the lowermost layer. In other words, heat is transferred to the fourth heat transfer member 61 through the third heat transfer members 31 positioned in the lowermost layer rather than the first heat transfer members 4 positioned in the lowermost layer.

### (Operation of Thermoelectric Conversion Device)

According to the thermoelectric conversion device 100 of this embodiment configured as described above, in addition to successful acquisition of operations and effects similar to those according to the fifth embodiment, the following operations and effects can be further achieved successfully.

In other words, by using a heat dissipation or cooling effect using the third heat transfer members 31, the cold junction sides of the first thermoelectric conversion film 10 and the side of the second thermoelectric conversion film 11 (in other words, the side of the front end portion 10b of the first thermoelectric conversion film 10 and the side of the rear end portion 11a of the second thermoelectric conversion film 11) can be effectively cooled through the third heat transfer members 31 positioned in the lowermost layer (the first layer). For this reason, as a result, the cold junction sides of the first thermoelectric conversion film 10 and the second thermoelectric conversion film 11 of each layer can be effectively cooled through the third heat transfer members 31 of each layer.

In addition, since the heat dissipation or cooling effect of the fourth heat transfer member 61 can be used, the cold junction sides of the first thermoelectric conversion film 10 and the second thermoelectric conversion film 11 of each layer can be cooled further more effectively through the third heat transfer members 31 of each layer. Accordingly, a temperature difference between the hot junction side and the cold junction side in the first thermoelectric conversion film 10 and the second thermoelectric conversion film 11 of each layer can be effectively increased, and a large amount of generated power can be achieved.

### (Modified Example of Sixth Embodiment)

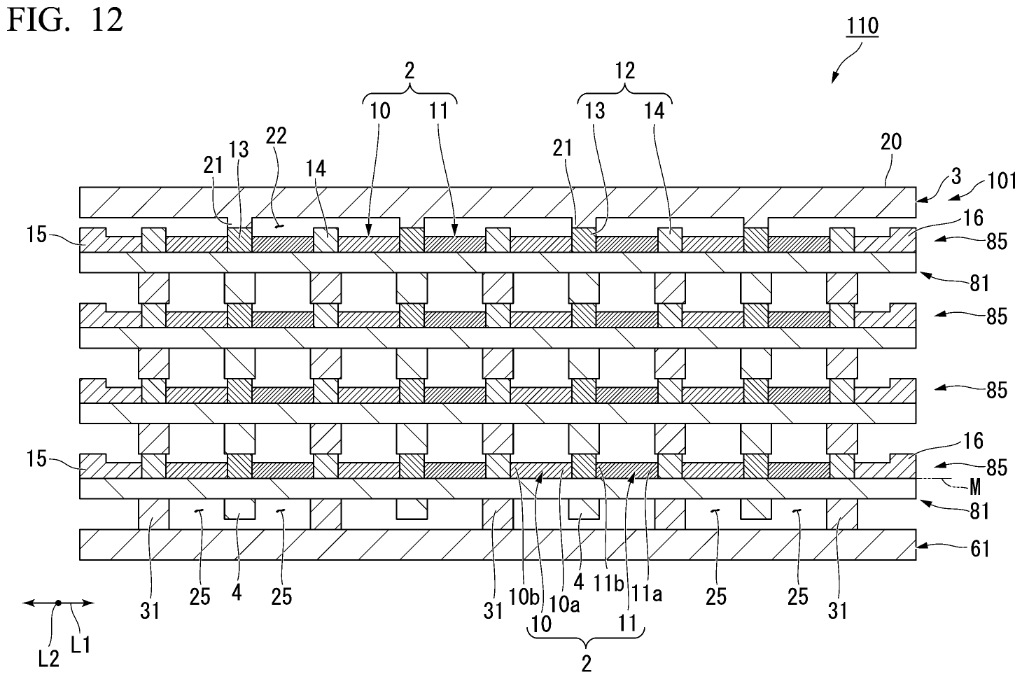

In the sixth embodiment described above, although the convex parts 62 are disposed in the fourth heat transfer member 61, the convex parts 62 are not essential and may not be included. For example, similar to the modified example of the third embodiment, as illustrated in FIG. 12, a thermoelectric conversion device 110 including a fourth heat transfer member 61 of which the upper face is a flat face may be configured.

In such a case, for example, the thickness of the first heat transfer member 4 positioned in the lowermost layer (the first layer) may be smaller than the thickness of the third heat transfer member 31. In other words, a length of the first heat transfer member 4 directed from the substrate 81 toward the fourth heat transfer member 61 in the thickness direction (a vertical direction perpendicular to the virtual plane M) may be smaller than a length of the third heat transfer member 31 directed from the substrate 81 toward the fourth heat transfer member 61 in the thickness direction (a vertical direction perpendicular to the virtual plane M).

In this way, heat is transferred to the fourth heat transfer member 61 through the third heat transfer members 31 rather than the first heat transfer members 4.

In the example illustrated in FIG. 12, although the fourth heat transfer member 61 is directly bonded to the third heat transfer members 31, the fourth heat transfer member 61 may be bonded to the third heat transfer members 31 through other members such as the paste-like materials described above or the like.

Also in the case of the thermoelectric conversion device 110 configured in such a way, operations and effects similar to those of the sixth embodiment can be successfully achieved.

As above, while the embodiments of the present disclosure have been described, such embodiments are presented as examples and are not intended to limit the scope of the disclosure. Each embodiment can be realized in other various forms, and, in a range not departing from the concept of the disclosure, various omissions, substitutions, and changes can be implemented, and modified examples of each embodiment may be appropriately combined. In addition, these embodiments and the modified examples thereof, for example, include elements that could have been easily conceived by a person skilled in the art, elements that are substantially the same, elements included in an equivalent scope, and the like.

For example, in each embodiment described above, although the second heat transfer member 3 is formed in one flat plate shape formed with the same shape and the same size as those of the thermoelectric conversion circuit modules 5 and 85, the configuration is not limited to such a case, and the second heat transfer member 3 may be formed using a plurality of members.

In addition, in each embodiment described above, although the thermoelectric conversion film 2 has been described as an example of the thermoelectric conversion elements, the thermoelectric conversion elements is not limited to a film and, for example, may be a bulk thermoelectric conversion element or the like.

In addition, in each embodiment described above, although the convex parts 21 formed integrally with the second heat transfer member 3 have been described as heat transfer parts as an example, the convex parts 21 do not need to be formed integrally with the second heat transfer member 3. For example, the second heat transfer member 3 may be formed in a flat plate shape, and convex parts that are separate from the second heat transfer member 3 may be disposed between the second heat transfer member 3 and the first electrodes 13. In such a case, for example, the convex parts can be formed using a different material from that of the second heat transfer member 3, and accordingly, the degree of freedom in selection of a material can be improved.

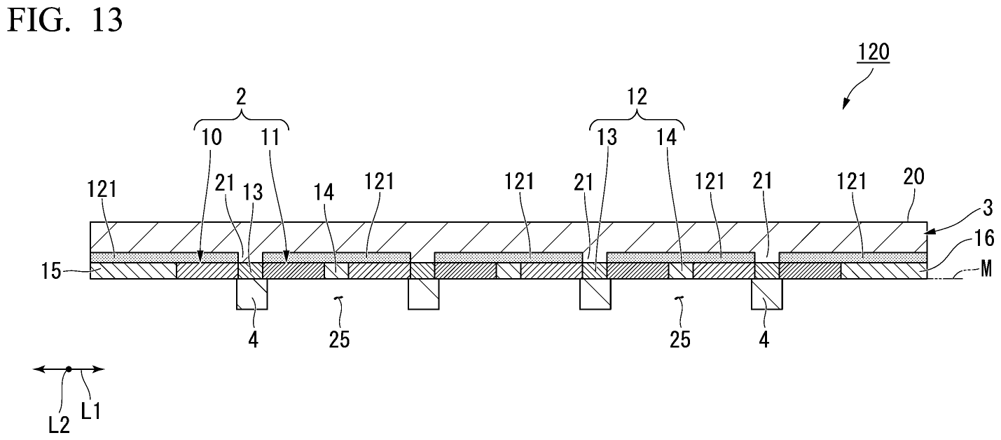

In addition, in each embodiment described above, although the gap portion 22 that is an air layer, of which thermal conductivity is lower than the thermal conductivity of the convex part 21, is formed between the convex parts 21 adjacent to each other in the first direction L1, in other words, the air gap portion 22 that is an air layer is formed between the lower face of the second heat transfer member 3 except for positions at which the convex parts 21 are formed, the thermoelectric conversion film 2, and the second electrode 14, the present disclosure is not limited to such a case. For example, as illustrated in FIG. 13, a thermoelectric conversion device 120 in which low heat conduction members 121 having lower thermal conductivity than the convex part 21 as first low heat conduction parts are formed on the lower face side of the second heat transfer member 3 to replace the air gap portions 22 that are air layers may be configured. Also in such a case, heat received from the second heat transfer member 3 can be transferred to the first electrodes 13 through the convex parts 21 with priority, and heat can be transferred from the first electrodes 13 to an end portion of the thermoelectric conversion film 2 on the hot junction side.

In addition, in the example illustrated in FIG. 13, the thickness of each of the first electrode 13, the second electrode 14, the first terminal 15, and the second terminal 16 is the same as that of the thermoelectric conversion film 2. Accordingly, the thickness of the entire thermoelectric conversion device 120, for example, can be thinned more than that of the case according to the first embodiment, and thinning and compactification of the thermoelectric conversion device can be achieved.

In addition, in each embodiment described above, heat transfer parts are not limited to the convex parts 21. For example, upper end surfaces of the first electrodes 13 may be brought into contact with the lower face of the second heat transfer member 3 formed in a flat plate shape by causing the first electrodes 13 to protrude to the side above from the thermoelectric conversion films 2, the second electrodes 14, the first terminals 15, and the second terminals 16.

Also in such a case, heat received from the second heat transfer member 3 can be transferred to the first electrodes 13 with priority, and heat can be transferred from the first electrodes 13 to end portions of the thermoelectric conversion films 2 on the hot junction side. Accordingly, in this case, the first electrodes 13 can function as heat transfer parts.

The heat transfer parts may transfer heat to/from the thermoelectric conversion films 2 through the heat transfer parts with priority rather than transferring heat to/from the thermoelectric conversion films 2 without passing through the heat transfer parts and may employ various configurations.

In addition, in each embodiment described above, the first electrodes 13 and the second electrodes 14 are not essential and thus may not be included.

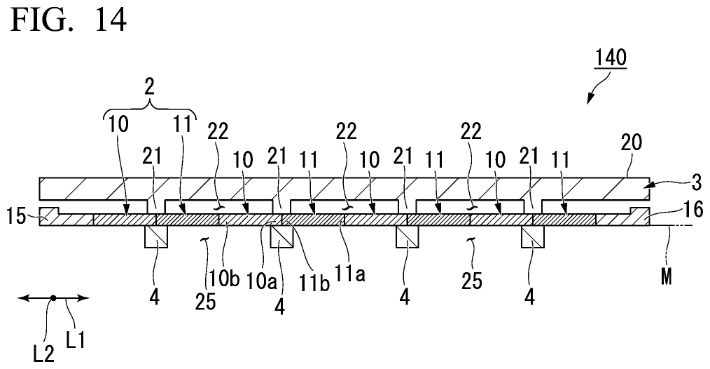

For example, in a thermoelectric conversion device 140 illustrated in FIG. 14, first thermoelectric conversion films 10 and second thermoelectric conversion films 11 are alternately disposed in the first direction L1, and each of the first thermoelectric conversion films 10 and each of the second thermoelectric conversion films 11 are combined to be in contact with each other. Convex parts 21 formed integrally with the second heat transfer member 3 are disposed to be bonded to the rear end portion 10a of the first thermoelectric conversion film 10 and the front end portion 11b of the second thermoelectric conversion film 11, for example, similar to the first embodiment, through insulating members.

Also in such a case, for example, the operations and effects similar to those according to the first embodiment can be successfully achieved.

In addition, in each embodiment described above, although the thermoelectric conversion film 2 is composed of the first thermoelectric conversion film 10 that is an n-type semiconductor and the second thermoelectric conversion film 11 that is a p-type semiconductor, the configuration is not limited to that of such a case, and a thermoelectric conversion film formed by any one of an n-type semiconductor and a p-type semiconductor may be used.

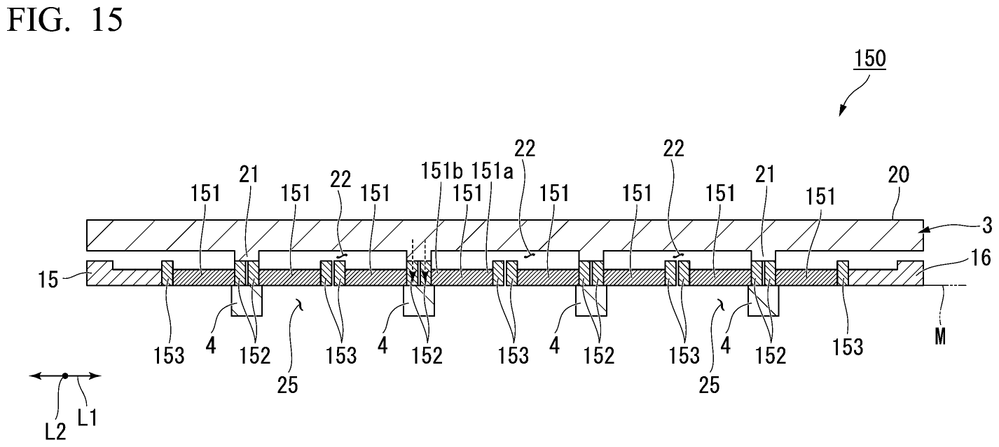

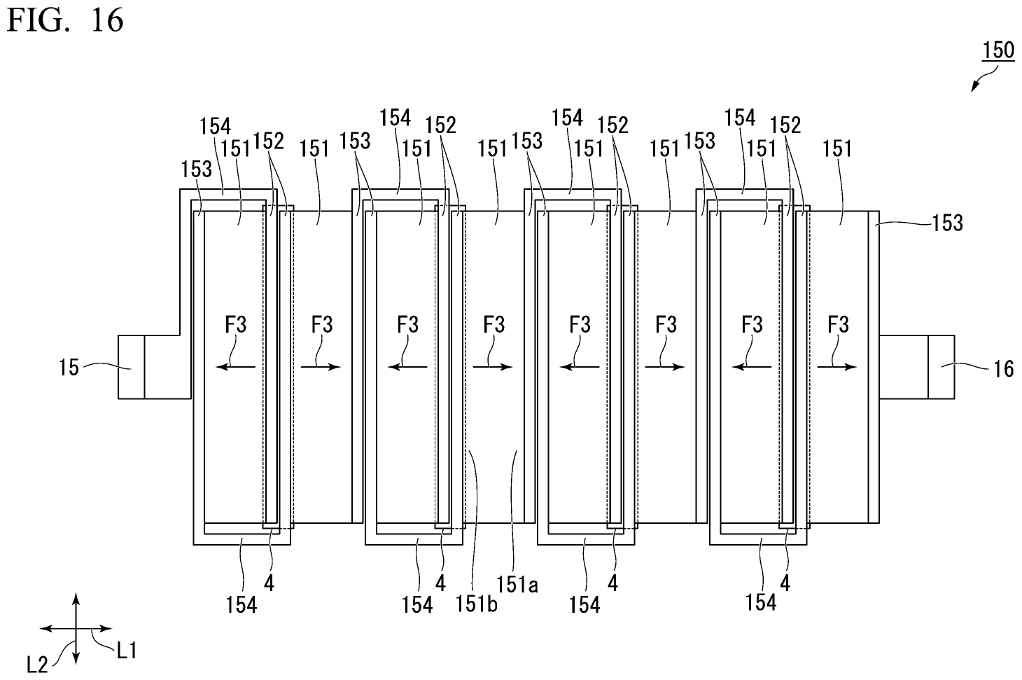

For example, a thermoelectric conversion device 150 illustrated in FIGS. 15 and 16 includes a plurality of thermoelectric conversion films (thermoelectric conversion elements according to the present disclosure) 151 that are p-type semiconductors. In addition, the thermoelectric conversion films 151 may be n-type semiconductors.

The thermoelectric conversion films 151 are disposed to be aligned with a constant space interposed therebetween in the first direction L1. The thermoelectric conversion films 151, for example, similar to the first embodiment, are formed in a rectangular shape that is longer in the second direction L2 than in the first direction L1 in plan view.

A plurality of first electrodes 152 functioning as hot junctions and a plurality of second electrodes 153 functioning as cold junctions are disposed and bonded between a plurality of thermoelectric conversion films 151. The first electrode 152 and the second electrode 153 are disposed for each thermoelectric conversion film 151.

More specifically, the first electrode 152 and the second electrode 153 are disposed on the side of the front end portion 151b or the side of the rear end portion 151a of the thermoelectric conversion film 151 such that the thermoelectric conversion film 151 is interposed therebetween in the first direction L1 and are brought into contact with the thermoelectric conversion film 151. The first electrode 152 and the second electrode 153 are formed over the entire length of the thermoelectric conversion film 151 in the second direction L2.

The first electrode 152 disposed in each thermoelectric conversion film 151 is formed such that it is disposed under the convex part 21. Accordingly, in a relationship between thermoelectric conversion films 151 adjacent to each other in the first direction L1, the first electrodes 152 and the second electrodes 153 that are respectively bonded together are adjacently disposed with a slight gap interposed therebetween in the first direction L1.

In addition, for example, insulating members not illustrated in the drawings are disposed between first electrodes 152 adjacent to each other in the first direction L1 and between second electrodes 153 adjacent to each other in the first direction L1. Accordingly, the first electrodes 152 adjacent to each other in the first direction L1 and the second electrodes 153 adjacent to each other in the first direction L1 are respectively combined through the insulating members.

A connection electrode 154, a first terminal 15, and a second terminal 16 are further connected to the first electrode 152 and the second electrode 153.

In the thermoelectric conversion films 151 adjacent to each other in the first direction L1, the connection electrode 154 is formed to be connected to the first electrode 152 disposed in one thermoelectric conversion film 151 and the second electrode 153 disposed in the other thermoelectric conversion film 151. The connection electrode 154 is formed to wrap around the thermoelectric conversion film 151 from the outside in the second direction L2.

The first terminal 15 is formed to be positioned on the side further forward from the second electrode 153 disposed in the thermoelectric conversion film 151 positioned furthest forward and is connected to the first electrode 152 disposed in the thermoelectric conversion film 151 positioned furthest forward with the connection electrode 154 therebetween. The second terminal 16 is formed to be positioned on the side to the rear of the second electrode 153 disposed in the thermoelectric conversion film 151 positioned furthest rearward and is brought into contact with the second electrode 153.

In this way, the thermoelectric conversion films 151 can be electrically connected in series through the connection electrode 154, and an electromotive force can be extracted from the thermoelectric conversion device 150 through the first terminal 15 and the second terminal 16.

Also in the case of the thermoelectric conversion device 150 configured in this way, for example, only a method of causing a current to flow through the thermoelectric conversion film 151 is different from that according to the first embodiment, and similar operations and effects can be successfully achieved.

More specifically, as denoted using a dotted-line arrow illustrated in FIG. 15, heat received from the second heat transfer member 3 through a heat-receiving face 20 can be transferred to the first electrodes 152 through the convex parts 21 with priority, and heat can be transferred from the first electrodes 152 to the front end portions 151b or the rear end portions 151a of the thermoelectric conversion film 151 (end portions of the thermoelectric conversion films 151 on the hot junction side). Since the thermoelectric conversion film 151 is a p-type semiconductor, a current as denoted using an arrow F3 illustrated in FIG. 16 flows from the side of the first electrode 152 that is a hot junction to the side of the second electrode 153 that is a cold junction.

At this time, since the connection electrode 154 is formed, as a result, an electromotive force in the same direction can be generated in each thermoelectric conversion film 151, and the electromotive force generated in each thermoelectric conversion film 151 can be extracted as a total electromotive force through the first terminal 15 and the second terminal 16.

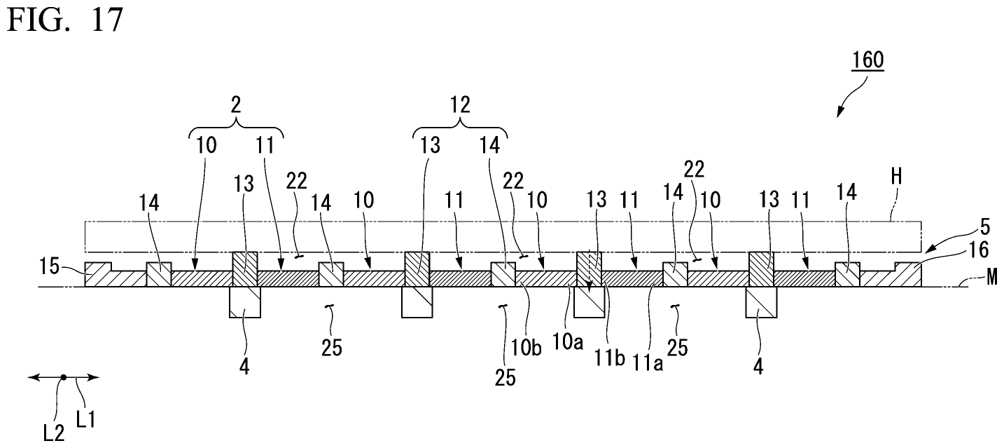

Accordingly, also in the case of the thermoelectric conversion device 150 illustrated in FIGS. 16 and 17, operations and effects similar to those according to the first embodiment can be successfully achieved.

In addition, in each of the embodiments and the modified examples thereof described above, for example, although a configuration not including the substrate 81 illustrated in the fourth second embodiment is included, the configuration is not limited to that of such a case, and the substrate 81 illustrated in the fourth embodiment or various substrates corresponding thereto may be combined as necessary.

In addition, in a case in which the substrate 81 is included as illustrated in the fourth embodiment, for example, a first heat transfer member may be formed using a part of the substrate 81.

In addition, in each embodiment described above, although a case in which the second heat transfer member 3 is included has been described as an example, the second heat transfer member 3 is not an essential component and thus may not be included.

For example, as illustrated in FIG. 17, a thermoelectric conversion device 160 having a configuration achieved by omitting the second heat transfer member 3 from the first embodiment may be used. In addition, in the form illustrated in FIG. 17, the same reference signs are assigned to the same parts as constituent elements according to the first embodiment, and description thereof will be omitted.

In addition to the second heat transfer member 3 not being included, the thermoelectric conversion device 160 causes the first electrodes 13 to function as heat transfer parts, which is different from the first embodiment. The other components are similar to those according to the first embodiment.

In this thermoelectric conversion device 160, the first electrodes 13 protrude to the side above from thermoelectric conversion films 2, second electrodes 14, a first terminal 15, and a second terminal 16. An upper end surface of the first electrode 13 is thermally bonded to a heat source H. Accordingly, heat from the heat source H can be transferred to an end portion of the thermoelectric conversion film 2 on the hot junction side, in other words, a rear end portion 10a of a first thermoelectric conversion film 10 and a front end portion 11b of the second thermoelectric conversion film 11 with priority through the first electrodes 13.

Accordingly, also in the case of the thermoelectric conversion device 160 configured as such operations and effects similar to those according to the first embodiment can be successfully obtained. Particularly, in accordance with no inclusion of the second heat transfer member 3, the entire thickness of the thermoelectric conversion device 160 can be configured to be thinner than that according to the first embodiment, and it is thus easy to achieve thinning and compactification.

In addition, although one example of the thermoelectric conversion device 160 not including the second heat transfer member 3 using the first embodiment as a base has been described with reference to FIG. 17, a configuration not including the second heat transfer member 3 in any other embodiments may be employed.

Furthermore, in each embodiment described above, although a case in which heat is transferred from the side of the second heat transfer member 3 to the side of the thermoelectric conversion film 2 has been described as an example, the present disclosure is not limited to such a case, and, as described above, a case in which heat is transferred from the side of the first heat transfer member 4 to the side of the thermoelectric conversion film 2 may be employed.

For example, brief description will be given using the thermoelectric conversion device 1 according to the first embodiment illustrated in FIGS. 1 to 3 as an example.

In the thermoelectric conversion device 1, for example, in a case in which a heat source not illustrated in the drawing is present on the side of the first heat transfer member 4, heat is received by the first heat transfer member 4 from the heat source. At this time, since the air gap portion 25, which is an air layer, is disposed between the first heat transfer members 4 that are adjacent to each other in the first direction L1, heat transfer to/from the thermoelectric conversion film 2 through the first heat transfer member 4 can be performed with priority over heat transfer through the air gap portion 25. Accordingly, also in a case in which heat is transferred from the side of the first heat transfer member 4 to the thermoelectric conversion film 2, a temperature difference between the hot junction side and the cold junction side in the thermoelectric conversion film 2 can be caused to occur.

In addition, since the second heat transfer member 3, for example, can be caused to function as a heat dissipation or cooling member or the like, by using a heat dissipation or cooling effect using the second heat transfer member 3, heat transferred from the first heat transfer member 4 to the thermoelectric conversion film 2 can be easily released to the convex parts 21 and the side of the second heat transfer member 3 rather than the heat being conducted from the hot junction side to the cold junction side inside the thermoelectric conversion film 2. In this way, in a case in which the amount of heat received from the side of the first heat transfer member 4 is large, a part of the heat can be released through the convex parts 21 and the second heat transfer member 3, and excessive heat can be inhibited from flowing into the side of the thermoelectric conversion film 2.

Accordingly, a decrease in the temperature difference occurring between the hot junction side and the cold junction side in the thermoelectric conversion film 2 can be inhibited.

In addition, since each air gap portion 22, which is an air layer, is disposed between the convex parts 21 that are adjacent to each other in the first direction L1, it becomes difficult for heat transferred to the convex parts 21 to be transferred in the in-plane direction of the virtual plane M through the air gap portions 22. Accordingly, a decrease in the temperature difference occurring between the hot junction side and the cold junction side in the thermoelectric conversion film 2 can be suppressed, and a large amount of generated power can be achieved.

In addition, although a case in which heat is transferred from the side of the first heat transfer member 4 to the side of the thermoelectric conversion film 2 has been described using the thermoelectric conversion device 1 according to the first embodiment as an example, the case is not limited to the first embodiment but can be applied to all the embodiments and the modified examples thereof, and similar operations and effects can be successfully achieved in any of the cases.

Particularly, the thermoelectric conversion device 60 of the third embodiment illustrated in FIG. 7, the thermoelectric conversion device 70 of the modified example of the third embodiment illustrated in FIG. 8, the thermoelectric conversion device 100 of the sixth embodiment illustrated in FIG. 11, and the thermoelectric conversion device 110 of the modified example of the sixth embodiment illustrated in FIG. 12 can be appropriately used in a case in which heat is transferred from the side of the first heat transfer member 4.

In other words, since each of the thermoelectric conversion devices 60, 70, 100, and 110 described above includes the fourth heat transfer member 61, the fourth heat transfer member 61 can be used as a heat-receiving member in a case in which heat is transferred from the side of the first heat transfer member 4. In addition, the fourth heat transfer member 61 is thermally bonded to the third heat transfer member 31 from the side below and transfers heat to/from the thermoelectric conversion film 2 through the third heat transfer member 31 rather than through the first heat transfer member 4. Accordingly, heat received from the fourth heat transfer member 61 can be transferred to the second electrodes 14 through the third heat transfer member 31 with priority and can be transferred from the second electrodes 14 to the thermoelectric conversion films 2.

In addition, in this case, the second electrodes 14 function as hot junctions, and the first electrodes 13 function as cold junctions. For this reason, the rear end portion 10a of the first thermoelectric conversion film 10 and the front end portion 11b of the second thermoelectric conversion film 11 function as end portions of the cold junction side, and the front end portion 10b of the first thermoelectric conversion film 10 and the rear end portion 11a of the second thermoelectric conversion film 11 function as end portions of the hot junction side.

Also in this case, as described above, heat received from the fourth heat transfer member 61 can be transferred to the thermoelectric conversion films 2 through the third heat transfer members 31 and the second electrodes 14 with priority, and a temperature difference between the hot junction side and the cold junction side in the thermoelectric conversion film 2 can be caused to occur.

In addition, the second heat transfer member 3 can be caused to function as a heat dissipation or cooling member or the like, and accordingly, the heat dissipation or cooling effect using the second heat transfer member 3 can be used. In this way, a temperature difference between the hot junction side and the cold junction side in the thermoelectric conversion film 2 can be caused to occur more effectively.

From the description presented above, in a case in which heat is transferred from the side of the first heat transfer member 4, the thermoelectric conversion devices 60, 70, 100, and 110 can be appropriately used.

In addition, in each of the embodiments described above, heat may be transferred from both the side of the first heat transfer member 4 and the side of the second heat transfer member 3 to the side of the thermoelectric conversion film 2 side.

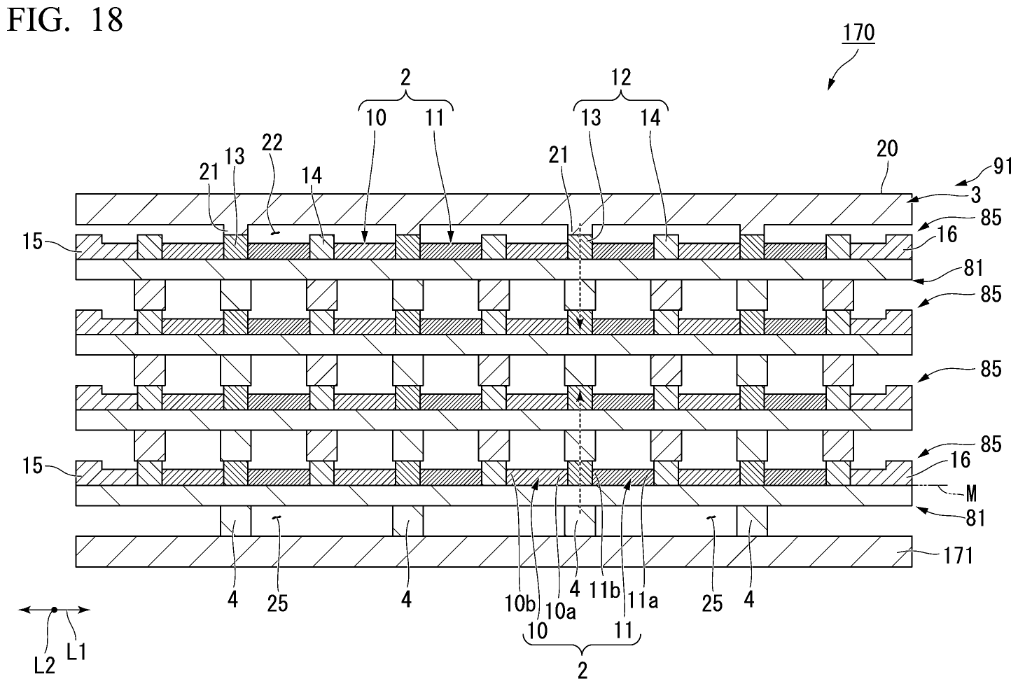

For example, a thermoelectric conversion device 170 illustrated in FIG. 18 may be configured. In addition, in the form illustrated in FIG. 18, the same reference signs will be assigned to the same parts as the constituent elements of the fifth embodiment, and description thereof will be omitted.

The thermoelectric conversion device 170 further includes a flat plate-shaped fifth heat transfer member (a fifth heat transfer member according to the present disclosure) 171 disposed under first heat transfer members 4 positioned in the lowermost layer (the first layer).

The fifth heat transfer member 171, similar to a second heat transfer member 3, functions as a heat-receiving member of the thermoelectric conversion device 170. In other words, in the form illustrated in FIG. 18, the second heat transfer member 3 functions as an upper heat-receiving member, and the fifth heat transfer member 171 functions as a lower heat-receiving member.

The fifth heat transfer member 171 is formed in a rectangular shape that is longer in the first direction L1 than in the second direction L2 in plan view in correspondence with the shape of the second heat transfer member 3. In the example illustrated in FIG. 18, the fifth heat transfer member 171 is formed in a size equal to that of the external shape of the second heat transfer member 3.

However, the size is not limited to that of this case, and the fifth heat transfer member 171, for example, may be formed in a flat plate shape having an external size larger than that of the second heat transfer member 3.

In addition, as a material of the fifth heat transfer member 171, for example, similar to the second heat transfer member 3, a material having high thermal conductivity is preferable, and, for example, a metal material such as aluminum (Al), copper (Cu), or the like is particularly preferable.

The fifth heat transfer member 171 is bonded to the first heat transfer members 4 positioned in the lowermost layer (the first layer) in the thermoelectric conversion circuit module 85. At this time, the fifth heat transfer member 171 may be bonded to the first heat transfer members 4 through other members such as the paste-like material described above or the like.

In addition, in the example illustrated in FIG. 18, although the upper face of the fifth heat transfer member 171 is configured as a flat face, the configuration is not limited to this case, and, for example, similar to the fourth heat transfer member 61 according to the sixth embodiment, the fifth heat transfer member 171 may be bonded to the first heat transfer members 4 through convex parts.

The fifth heat transfer member 171 is thermally bonded to the first heat transfer members 4 positioned in the lowermost layer (the first layer) and transfers heat to/from the thermoelectric conversion films 2 positioned in the lowermost layer through the first heat transfer members 4 positioned in the lowermost layer rather than through air gap portions 25 positioned in the lowermost layer. In other words, heat is transferred from the fifth heat transfer member 171 to the thermoelectric conversion film 2 positioned in the lowermost layer through the first heat transfer members 4 positioned in the lowermost layer rather than through the air gap portions 25 positioned in the lowermost layer.

### (Operation of Thermoelectric Conversion Device)

According to the thermoelectric conversion device 170 configured as described above, dissipated heat can be effectively used, and power generation in the thermoelectric conversion films 2 of each layer can be achieved. Accordingly, a large amount of generated power can be achieved with a high efficiency.

In other words, according to this thermoelectric conversion device 170, as denoted using a dotted-line arrow illustrated in FIG. 18, heat received from the second heat transfer member 3 can be transferred to the first electrodes 13 positioned in the uppermost layer (the fourth layer) through the convex parts 21 with priority and can be transferred to hot junction sides in the first thermoelectric conversion film 10 and the second thermoelectric conversion film 11 positioned in the uppermost layer (in other words, the rear end portion 10a of the first thermoelectric conversion film 10 and the front end portion 11b of the second thermoelectric conversion film 11) through these first electrodes 13.

In addition, heat transferred to the first electrodes 13 positioned in the uppermost layer can be transferred to the first electrodes 13 positioned in the third layer through the first heat transfer members 4 positioned in the uppermost layer and can be transferred to hot junction sides in the first thermoelectric conversion film 10 and the second thermoelectric conversion film 11 positioned in the third layer through these first electrodes 13.

Simultaneously with this, as denoted using the dotted-line arrow illustrated in FIG. 18, the heat received from the fifth heat transfer member 171 can be transferred to the first electrodes 13 positioned in the lowermost layer through the first heat transfer members 4 positioned in the lowermost layer (the first layer) with priority and can be transferred to the hot junction sides in the first thermoelectric conversion film 10 and the second thermoelectric conversion film 11 positioned in the lowermost layer through these first electrodes 13.

In addition, the heat transferred to the first electrodes 13 positioned in the lowermost layer can be transferred to the first electrodes 13 positioned in the second layer through the first heat transfer members 4 positioned in the second layer and can be transferred to the hot junction sides in the first thermoelectric conversion film 10 and the second thermoelectric conversion film 11 positioned in the second layer through these first electrodes 13.

Accordingly, the heat dissipated as described above can be effectively used, and, by achieving power generation in the thermoelectric conversion film 2 of each layer, a large amount of generated power can be achieved with a high efficiency.

In addition, by supplying an air flow such as a cooling wind or the like to the thermoelectric conversion device 170, for example, from the lateral side thereof (a direction along the virtual plane M), also in a case in which heat is transferred from both the side of the second heat transfer member 3 and the side of the fifth heat transfer member 171, heat dissipation from the thermoelectric conversion device 170 to the outside can be appropriately performed.

In addition, in the thermoelectric conversion device 170 illustrated in FIG. 18, as described above, also in a case in which heat is not transferred from both the side of the second heat transfer member 3 and the side of the fifth heat transfer member 171, and heat is transferred from the side of the fifth heat transfer member 171, the thermoelectric conversion device 170 can be appropriately used. In this case, the second heat transfer member 3 can be used as a heat dissipation or a cooling member, and the fifth heat transfer member 171 can be used as a heat-receiving member.

### INDUSTRIAL APPLICABILITY

According to the present disclosure, excessive heat can be inhibited from flowing into the side of the thermoelectric conversion elements, and a temperature difference occurring between the hot junction side and the cold junction side in the thermoelectric conversion elements is secured, and a large amount of generated power can be achieved, whereby a high-quality and high-performance thermoelectric conversion device having a superior thermoelectric conversion efficiency can be achieved. Therefore, there is industrial applicability.

### REFERENCE SIGNS LIST

M virtual plane

1, 30, 40, 50, 60, 70, 80, 90, 100, 110, 120, 140, 150, 160, 170 thermoelectric conversion device

2, 151 thermoelectric conversion film (thermoelectric conversion elements)

3 second heat transfer member (second heat transfer member)

4 first heat transfer member (first heat transfer member)

21 convex part (heat transfer part)

22 air gap portion (first low heat conduction part)

25 air gap portion (second low heat conduction part)

31 third heat transfer member (third heat transfer member)

61 fourth heat transfer member (fourth heat transfer member)

81 substrate

82 first principal surface (first surface)

83 second principal surface (second surface)

91, 101 thermoelectric conversion module

121 low heat conduction member (first low heat conduction part)

171 fifth heat transfer member (fifth heat transfer member)

1. A thermoelectric conversion device, comprising:
thermoelectric conversion elements that are disposed on a virtual plane;
a plurality of first heat transfer members that are disposed on one side with respect to the thermoelectric conversion elements in a vertical direction perpendicular to the virtual plane and that are configured to transfer heat to/from the thermoelectric conversion elements; and
a plurality of heat transfer parts that are disposed on an other side with respect to the thermoelectric conversion elements in the vertical direction perpendicular to the virtual plane with a space interposed therebetween in a first direction along an in-plane direction of the virtual plane, and that are configured to transfer heat to/from the thermoelectric conversion elements,
wherein the first heat transfer members are disposed in correspondence with the heat transfer parts and are disposed to be positioned on the one side in the vertical direction opposite to the heat transfer parts,
wherein a first low heat conduction part having lower thermal conductivity than thermal conductivity of the heat transfer parts is disposed between the heat transfer parts that are adjacent to each other in the first direction, and
wherein a second low heat conduction part having lower thermal conductivity than thermal conductivity of the first heat transfer members is disposed between the first heat transfer members that are adjacent to each other in the first direction.

2. The thermoelectric conversion device according to claim 1, further comprising a second heat transfer member disposed on the other side with respect to the thermoelectric conversion elements in the vertical direction,
wherein the heat transfer parts are disposed on a side of the thermoelectric conversion elements with respect to the second heat transfer member.

3. The thermoelectric conversion device according to claim 1,
wherein the first low heat conduction part and the second low heat conduction part are air gap portions.

4. The thermoelectric conversion device according to claim 1, further comprising a substrate that includes a first surface and a second surface facing each other in the vertical direction and is disposed along the virtual plane,
wherein the substrate is disposed between the thermoelectric conversion elements and the first heat transfer members in a state in which the first surface is directed toward a side of the thermoelectric conversion elements, and the second surface is directed toward a side of the first heat transfer members.

5. The thermoelectric conversion device according to claim 1,
wherein the second low heat conduction part is disposed at a middle position of the first heat transfer members that are adjacent to each other in the first direction.

6. The thermoelectric conversion device according to claim 1, further comprising third heat transfer members that are disposed on the one side with respect to the thermoelectric conversion elements in the vertical direction and that are configured to transfer heat to/from the thermoelectric conversion elements,
wherein each of the third heat transfer members is disposed at a middle position of the first heat transfer members that are adjacent to each other in the first direction and each of the third heat transfer members has higher thermal conductivity than the second low heat conduction part.

7. The thermoelectric conversion device according to claim 6, wherein a width of the first heat transfer member in the first direction is larger than a width of the third heat transfer member in the first direction.

8. The thermoelectric conversion device according to claim 6, wherein a width of the third heat transfer member in the first direction is larger than a width of the first heat transfer member in the first direction.

9. The thermoelectric conversion device according to claim 6, further comprising a fourth heat transfer member disposed on the one side with respect to the first heat transfer members and the third heat transfer members in the vertical direction,
wherein the fourth heat transfer member are thermally bonded to the third heat transfer members and are configured to transfer heat to/from the thermoelectric conversion elements through the third heat transfer members rather than through the first heat transfer members.

10. The thermoelectric conversion device according to claim 1, further comprising a thermoelectric conversion module in which the thermoelectric conversion elements and the first heat transfer members are piled up in the vertical direction in multiple layers,
wherein, when a direction toward the other side in the vertical direction is set as an upward direction, the heat transfer parts are disposed on the other side in the vertical direction with respect to the thermoelectric conversion elements positioned in an uppermost layer in the vertical direction among the thermoelectric conversion elements piled up in multiple layers, and
wherein the thermoelectric conversion elements positioned in a layer other than the uppermost layer in the vertical direction among the thermoelectric conversion elements piled up in multiple layers are thermally bonded to the first heat transfer members positioned in a layer above thereof and are configured to transfer heat to/from the thermoelectric conversion elements positioned in the layer above through the first heat transfer members positioned in the layer above rather than through the second low heat conduction part positioned in the layer above.

11. The thermoelectric conversion device according to claim 1, further comprising a thermoelectric conversion module in which the thermoelectric conversion elements, the first heat transfer members, and the third heat transfer members are piled up in the vertical direction in multiple layers,
wherein, when a direction toward the other side in the vertical direction is set as an upward direction, the heat transfer parts are disposed on the other side in the vertical direction with respect to the thermoelectric conversion elements positioned in an uppermost layer in the vertical direction among the thermoelectric conversion elements piled up in multiple layers, and
wherein the thermoelectric conversion elements positioned in a layer other than the uppermost layer in the vertical direction among the thermoelectric conversion elements piled up in multiple layers are thermally bonded to the first heat transfer members and the third heat transfer members positioned in a layer above thereof and are configured to transfer heat to/from the thermoelectric conversion elements positioned in the layer above through the first heat transfer members and the third heat transfer members positioned in the layer above rather than through the second low heat conduction part positioned in the layer above.

12. The thermoelectric conversion device according to claim 11, further comprising a fourth heat transfer member disposed on the one side in the vertical direction with respect to the first heat transfer member and the third heat transfer member positioned in a lowermost layer in the vertical direction among the first heat transfer members and the third heat transfer members piled up in multiple layers,
wherein the fourth heat transfer member is thermally bonded to the third heat transfer members positioned in the lowermost layer and is configured to transfer heat to/from the thermoelectric conversion elements positioned in the lowermost layer through the third heat transfer members positioned in the lowermost layer rather than through the first heat transfer members positioned in the lowermost layer.

13. The thermoelectric conversion device according to claim 10, further comprising a fifth heat transfer member disposed on the one side in the vertical direction with respect to the first heat transfer members positioned in a lowermost layer in the vertical direction among the first heat transfer members piled up in multiple layers,
wherein the fifth heat transfer member is thermally bonded to the first heat transfer members positioned in the lowermost layer and is configured to transfer heat to/from the thermoelectric conversion elements positioned in the lowermost layer through the first heat transfer members positioned in the lowermost layer than through the second low heat conduction parts positioned in the lowermost layer.
